(19) United States
(12) Patent Application Publication
(10) Pub. No.: US 2026/0271262 A1
(43) Pub. Date: Sep. 10, 2026

(54) Semiconductor Device

(71) Applicant: Semiconductor Energy Laboratory Co., Ltd., Kanagawa-ken (JP)

(72) Inventors: Shunpei YAMAZAKI, Setagaya, Tokyo (JP); Takanori MATSUZAKI, Atsugi, Kanagawa (JP); Yuki OKAMOTO, Ebina, Kanagawa (JP); Hitoshi KUNITAKE, Machida, Tokyo (JP)

(73) Assignee: Semiconductor Energy Laboratory Co., Ltd., Kanagawa-ken (JP)

(21) Appl. No.: 19/166,382

(22) PCT Filed: Mar. 14, 2024
(86) PCT No.: PCT/IB2024/052440

§ 371 Date: Sep. 17, 2025

(30) Foreign Application Priority Data
Mar. 21, 2023 (JP) 2023-044833

(51) Int. Cl. H10B 12/00; G11C 11/405; G11C 11/4091

(52) U.S. Cl. CPC H10B 12/00; G11C 11/405; G11C 11/4091

(57) ABSTRACT

A semiconductor device with a novel structure is provided. First to third element layers are included. The second element layer is stacked over the first element layer. The third element layer is stacked over the second element layer. A first storage portion is provided in the second element layer. A second storage portion is provided in the third element layer. The first element layer includes a first sense amplifier circuit portion electrically connected to the first storage portion, and a second sense amplifier circuit portion electrically connected to the second storage portion. The first sense amplifier circuit portion and the second sense amplifier circuit portion each include a first transistor including a first semiconductor layer including silicon in a channel formation region. The first storage portion includes a second transistor including a second semiconductor layer including an oxide semiconductor in a channel formation region. The second storage portion includes a third transistor including a third semiconductor layer including an oxide semiconductor in a channel formation region. The third element layer provided with the second storage portion is provided by stacking a plurality of element layers.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Thus, more specific examples of the technical field of one embodiment of the present invention disclosed in this specification include a semiconductor device, a display device, a light-emitting device, a power storage device, a storage device (a memory unit), a driving method thereof, and a manufacturing method thereof.

### BACKGROUND ART

A CPU (central processing unit) performs a series of processing by successively executing processing corresponding to a program (data) stored in a memory. Data necessary for the processing is also stored in the memory. Thus, the speed at which the CPU accesses the memory or its power consumption significantly affects the arithmetic performance, power consumption, or the like of the CPU.

A structure where data on all memories can be accessed equally has broad utility but lowers the memory access speed of the CPU, resulting in decreased arithmetic performance and increased power consumption. Therefore, a memory hierarchical structure, that is, a structure in which a cache memory composed of SRAM or the like, a main storage device composed of DRAM or the like, an auxiliary storage device such as a flash memory or a hard disk, and the like are organized in order of proximity to the CPU is typically employed.

The main storage device (main memory) has a lower operating speed than the cache memory but can have a larger storage capacity (also referred to as memory capacity). The auxiliary storage device has an even lower operating speed than the main storage device but can have a larger storage capacity. The CPU basically accesses the cache memory; when desired data is not stored in the cache memory, the CPU accesses the main storage device, copies the data to the cache memory, and then accesses the data again. Furthermore, in the case where the desired data is not stored even in the main storage device, the CPU accesses the auxiliary storage device, copies the data to the main storage device and the cache memory, and then accesses the data again.

A common structure is a structure in which cache memories are arranged further hierarchically, that is, a structure in which a primary cache memory (primary cache, L1 cache), a secondary cache memory (secondary cache, L2 cache), a tertiary cache memory (tertiary cache, L3 cache), and the like are organized in order of proximity to the CPU.

Patent Document 1 discloses a structure in which a storage portion using a transistor including an oxide semiconductor in a semiconductor layer is used for a register, a cache memory, and a main storage device. The transistor including an oxide semiconductor in the semiconductor layer has a characteristic of an extremely low off-state current. Thus, when the transistor is used in the storage portion such as the register, the cache memory, or the main storage device, stored data can be retained for a long time.

### REFERENCE

### Patent Document

[Patent Document 1] Japanese Published Patent Application No. 2015-180994

### SUMMARY OF THE INVENTION

### Problems to be Solved by the Invention

In order to improve the performance of a semiconductor device, increasing the operating speed of the cache memory and increasing the storage capacity of the main memory are effective in addition to high-speed data transmission between the main memory and the cache memory. However, it has been difficult to achieve both an increase in operating speed of the cache memory and an increase in storage capacity of the main memory.

An object of one embodiment of the present invention is to provide a semiconductor device with a novel structure. Another object of one embodiment of the present invention is to provide a semiconductor device that excels in improving arithmetic performance, reducing power consumption, increasing operating speed, achieving downsizing, or increasing storage capacity.

Note that the objects of one embodiment of the present invention are not limited to the objects listed above. The objects listed above do not preclude the existence of other objects. Note that the other objects are objects that are not described in this section and are described below. The objects that are not described in this section can be derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device including a first element layer, a second element layer, and a third element layer. The second element layer is stacked over the first element layer. The third element layer is stacked over the second element layer. The second element layer is provided with a first storage portion. The third element layer is provided with a second storage portion. The first element layer includes a first sense amplifier circuit electrically connected to the first storage portion, and a second sense amplifier circuit electrically connected to the second storage portion. The first sense amplifier circuit and the second sense amplifier circuit each include a first transistor including a first semiconductor layer including silicon in a channel formation region. The first storage portion and the second storage portion each include a second transistor including a second semiconductor layer including an oxide semiconductor in a channel formation region. The third element layer provided with the second storage portion is a stack of a plurality of element layers.

One embodiment of the present invention is a semiconductor device including a first element layer, a second element layer, and a third element layer. The second element layer is stacked over the first element layer. The third element layer is stacked over the second element layer. The second element layer is provided with a first storage portion. The third element layer is provided with a second storage portion. The first element layer includes a first sense amplifier circuit electrically connected to the first storage portion, and a second sense amplifier circuit electrically connected to the second storage portion. The first sense amplifier circuit and the second sense amplifier circuit each include a first transistor including a first semiconductor layer including silicon in a channel formation region. The first storage portion includes a second transistor including a second semiconductor layer including an oxide semiconductor in a channel formation region. The second storage portion includes a third transistor including a third semiconductor layer including an oxide semiconductor in a channel formation region. The third element layer provided with the second storage portion is a stack of a plurality of element layers.

In the semiconductor device of one embodiment of the present invention, the oxide semiconductor preferably includes at least In.

In the semiconductor device of one embodiment of the present invention, the first storage portion preferably has a function of a cache memory of an arithmetic portion.

In the semiconductor device of one embodiment of the present invention, the second transistor is preferably a vertical transistor.

In the semiconductor device of one embodiment of the present invention, it is preferable that the second transistor include a first gate electrode and a second gate electrode, the first gate electrode be supplied with a signal for controlling an on or off state of the second transistor, and the second gate electrode be supplied with a potential for controlling electrical characteristics of the second transistor.

In the semiconductor device of one embodiment of the present invention, it is preferable that the second transistor be a planar transistor and the third transistor be a vertical transistor.

In the semiconductor device of one embodiment of the present invention, a switching circuit is preferably provided between the first storage portion and the first sense amplifier circuit and between the second storage portion and the second sense amplifier circuit.

Note that other embodiments of the present invention are shown in the description of the following embodiments and the drawings.

### Effect of the Invention

One embodiment of the present invention can provide a novel semiconductor device or the like. Another embodiment of the present invention can provide a semiconductor device that excels in improving arithmetic performance, reducing power consumption, increasing operating speed, achieving downsizing, or increasing storage capacity.

Note that the description of these effects does not preclude the existence of other effects. One embodiment of the present invention does not need to have all these effects. Other effects will be apparent from and can be derived from the description of the specification, the drawings, the claims, and the like.

### BRIEF DESCRIPTION OF THE DRAWINGS

FIG. 1A and FIG. 1B are schematic views illustrating a structure example of a semiconductor device.

FIG. 2 is a schematic view illustrating a structure example of a semiconductor device.

FIG. 3 is a schematic view illustrating a structure example of a semiconductor device.

FIG. 4A and FIG. 4B are schematic views illustrating structure examples of a semiconductor device.

FIG. 5 is a schematic view illustrating a structure example of a semiconductor device.

FIG. 6 is a diagram illustrating a structure example of a semiconductor device.

FIG. 7A and FIG. 7B are schematic views illustrating structure examples of a semiconductor device.

FIG. 8A to FIG. 8H are schematic views illustrating structure examples of a semiconductor device.

FIG. 9 is a schematic view illustrating a structure example of a semiconductor device.

FIG. 10 is a schematic view illustrating a structure example of a semiconductor device.

FIG. 11 is a block diagram illustrating a structure example of a semiconductor device.

FIG. 12 is a schematic view illustrating a structure example of a semiconductor device.

FIG. 13 is a schematic view illustrating a structure example of a semiconductor device.

FIG. 14A to FIG. 14D are circuit diagrams illustrating structure examples of a semiconductor device.

FIG. 15 is a circuit diagram illustrating a structure example of a semiconductor device.

FIG. 16 is a cross-sectional view illustrating a structure example of a semiconductor device.

FIG. 17A to FIG. 17C are cross-sectional views illustrating structure examples of a semiconductor device.

FIG. 18A is a diagram illustrating a structure example of a semiconductor device. FIG. 18B is a diagram illustrating an equivalent circuit of the semiconductor device.

FIG. 19 is a diagram illustrating a structure example of a semiconductor device.

FIG. 20A is a diagram illustrating a structure example of a semiconductor device. FIG. 20B is a diagram illustrating an equivalent circuit of the semiconductor device.

FIG. 21 is a schematic cross-sectional view illustrating a structure example of a semiconductor device.

FIG. 22A to FIG. 22C are plan views illustrating structure examples of a transistor included in a semiconductor device, and FIG. 22D is a cross-sectional view illustrating the structure example of the transistor included in the semiconductor device.

FIG. 23A is a plan view illustrating a structure example of a transistor included in a semiconductor device, and FIG. 23B is a cross-sectional view illustrating the structure example of the transistor included in the semiconductor device.

FIG. 24 is a schematic cross-sectional view illustrating a structure example of a semiconductor device.

FIG. 25A and FIG. 25B are diagrams each illustrating an example of an electronic component.

FIG. 26A and FIG. 26B are diagrams each illustrating an example of an electronic device. FIG. 26C to FIG. 26E are diagrams illustrating an example of a large computer.

FIG. 27 is a diagram illustrating an example of space equipment.

FIG. 28 is a diagram illustrating an example of a storage system that can be used in a data center.

FIG. 29A is a schematic top view of a memory device according to Example, and FIG. 29B and FIG. 29C are perspective views of the memory device.

FIG. 30A is a 3D image of a memory device according to Example, and FIG. 30B to FIG. 30D are cross-sectional SEM images of the memory device.

FIG. 31 shows the electrical characteristics of vertical transistors according to Example.

FIG. 32A and FIG. 32B are diagrams explaining the operating speed of a semiconductor device according to Example.

### MODE FOR CARRYING OUT THE INVENTION

Embodiments will be described below with reference to the drawings. The embodiments can be implemented with many different modes, and it will be readily appreciated by those skilled in the art that modes and details can be changed in various ways without departing from the spirit and scope thereof. Therefore, the present invention should not be construed as being limited to the description of the embodiments below.

In the drawings, the size, the layer thickness, or the region is exaggerated for clarity in some cases. Thus, the size, the layer thickness, or the region is not limited to the illustrated scale. Note that the drawings schematically illustrate ideal examples, and embodiments of the present invention are not limited to shapes, values, and the like illustrated in the drawings.

Unless otherwise specified, an off-state current in this specification and the like refers to a drain current of a transistor in an off state (also referred to as a non-conducting state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as OS), and the like. For example, in the case where a metal oxide is used for an active layer of a transistor, the metal oxide is referred to as an oxide semiconductor in some cases. That is, an OS transistor can also be referred to as a transistor including a metal oxide or an oxide semiconductor.

### Embodiment 1

A semiconductor device according to one embodiment of the present invention will be described with reference to drawings. Note that a semiconductor device refers to a device that utilizes semiconductor characteristics, and means a circuit including a semiconductor element (a transistor, a diode, a photodiode, or the like) and a device including the circuit. The semiconductor device described in this embodiment has a function of an arithmetic device including a storage portion that utilizes a transistor with an extremely low off-state current.

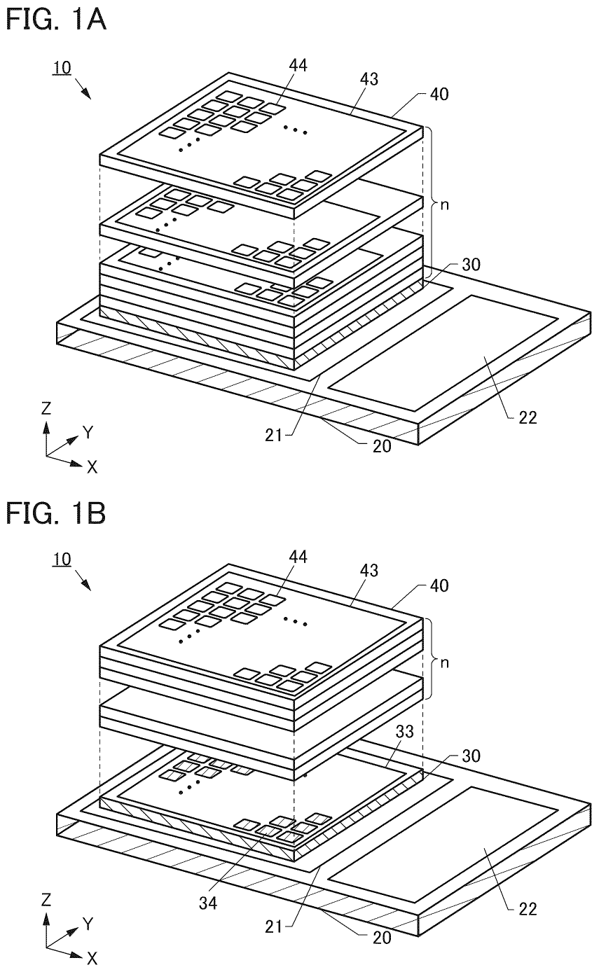

FIG. 1A and FIG. 1B are schematic views of a semiconductor device 10 described in this embodiment. FIG. 1B is a schematic view of the semiconductor device 10 described in this embodiment.

In the schematic views illustrated in FIG. 1A and FIG. 1B, components included in the semiconductor device 10 are illustrated apart from each other for easy understanding of the arrangement of the components.

In the schematic views illustrated in FIG. 1A and FIG. 1B, the direction perpendicular or substantially perpendicular to the surface of an element layer 20 is defined as a Z-axis direction in order to explain the arrangement of the components. Note that for easy understanding, the Z-axis direction is sometimes referred to as the direction perpendicular to the surface of the element layer 20 in this specification. Note that “substantially perpendicular” refers to a state where an arrangement angle is greater than or equal to 85 degrees and less than or equal to 95 degrees.

Note that in this specification, the drawings, and the like, an X direction, a Y direction, and a Z direction are sometimes defined to describe the arrangement of components. For example, in the schematic views illustrated in FIG. 1A and FIG. 1B, the X direction, the Y direction, and the Z direction are defined to describe the arrangement of the components included in the semiconductor device 10. The X direction, the Y direction, and the Z direction are perpendicular or substantially perpendicular to each other.

The semiconductor device 10 illustrated in FIG. 1A and FIG. 1B includes the element layer 20, an element layer 30 provided over the element layer 20, and n (n is an integer greater than or equal to 2) element layers 40 provided over the element layer 30. Note that an element layer refers to a layer where a semiconductor element such as a transistor or a capacitor is provided.

The element layer 20 includes sense amplifier circuits 21 and 22. The element layer 20 includes a transistor in which a semiconductor layer including a channel formation region includes silicon (a Si transistor). The element layer 20 is an element layer where a semiconductor layer including a channel formation region is provided in a silicon substrate or an element layer where a semiconductor layer of silicon including a channel formation region is bonded to a silicon substrate.

Although the substrate provided in the element layer 20 is a silicon substrate in the description, this embodiment is not limited thereto. Note that a silicon substrate refers to a substrate including silicon as a semiconductor material, for example, a single crystal silicon substrate. Note that, without being limited to silicon, a material containing Ge (germanium), SiGe (silicon germanium), GaAs (gallium arsenide), GaAlAs (gallium aluminum arsenide), or the like may be used for the substrate.

For the Si transistor included in the element layer 20, high-crystallinity silicon, such as single crystal silicon or polycrystalline silicon in particular, is used. When the element layer 20 includes high-crystallinity silicon, high field-effect mobility can be achieved and higher-speed operation is possible. Thus, an arithmetic portion, a peripheral circuit, and the like as well as the sense amplifier circuits 21 and 22 can be provided in the element layer 20.

The arithmetic portion that can be provided in the element layer 20 has a function of performing general-purpose processing such as execution of an operating system, control of data, various kinds of arithmetic operations, and execution of programs, like a CPU (Central Processing Unit) or a GPU (Graphics Processing Unit). In addition, a storage portion such as a register for retaining data used in the arithmetic portion is provided in the element layer 20 provided with the arithmetic portion.

In the case where the arithmetic portion is provided in the element layer 20, a hierarchical memory structure is effective in improving the arithmetic performance and reducing power consumption. In this case, a structure is effective in which a primary cache memory (primary cache, L1 cache), a secondary cache memory (secondary cache, L2 cache), and a ternary cache memory (tertiary cache, L3 cache) are provided in or around the arithmetic portion. In the case where storage portions such as the L1 cache to the L3 cache are provided in the element layer 20, the L1 cache to the L3 cache can be composed of SRAM.

The sense amplifier circuit 21 provided in the element layer 20 is a circuit for writing or reading data of a memory cell 34 included in a storage portion 33 provided in the element layer 30. The sense amplifier circuit 22 provided in the element layer 20 is a circuit for writing or reading data of a memory cell 44 included in a storage portion 43 provided in the element layer 40. When the sense amplifier circuits 21 and 22 are provided in the element layer 20, high-speed operation for data writing or reading is possible.

The element layer 30 includes a transistor in which a semiconductor layer including a channel formation region includes an oxide semiconductor (an OS transistor). The element layer 30 including OS transistors can be stacked over the element layer 20. FIG. 1A and FIG. 1B illustrate a state where the element layer 30 is stacked over the element layer 20 in the semiconductor device 10. When the element layer 30 is provided over the element layer 20, the transistor density per unit area can be increased.

Like the element layer 30, the element layers 40 includes OS transistors. The element layers 40 including OS transistors can be stacked over the element layer 30. FIG. 1A and FIG. 1B illustrate a state where the n element layers 40 are stacked over the element layer 30 in the semiconductor device 10. When the element layers 40 are provided over the element layer 30, the transistor density per unit area can be increased.

Examples of a metal oxide used in an OS transistor include an indium oxide (In oxide), a gallium oxide (Ga oxide), and a zinc oxide (Zn oxide). Moreover, as the metal oxide used in an OS transistor, an In—Zn oxide can be used. The metal oxide preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable to use an oxide containing indium (In), gallium (Ga), and zinc (Zn) (also referred to as IGZO) as the metal oxide. Alternatively, it is preferable to use an oxide containing indium, tin, and zinc (also referred to as ITZO). Alternatively, it is preferable to use an oxide containing indium, gallium, tin, and zinc (also referred to as IGTO). Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Alternatively, it is preferable to use an oxide containing indium (In), gallium (Ga), zinc (Zn), and tin (Sn) (also referred to as IGZTO). In the case where the metal oxide is an In-Zn oxide, examples of the atomic ratio of the metal elements in the In—Zn oxide include In:Zn=1:1, In:Zn=2:1, In:Zn=4:1, and a composition in the neighborhood of any of them. In addition, the In—Zn oxide may contain a slight amount of the element M. For example, in the case where Sn is contained as the element M, examples of the atomic ratio of the metal elements in the metal oxide include In:Sn:Zn=2:0.1:1, In:Sn:Zn=4:0.1:1, and a composition in the neighborhood of any of them.

For the metal oxide used in an OS transistor, two or more metal oxide layers with different compositions can be used. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed.

As another example, a stacked-layer structure of any one selected from indium oxide, indium gallium oxide, and IGZO and any one selected from IAZO, IAGZO, and ITZO may be employed, for example.

Note that the metal oxide used in an OS transistor preferably has crystallinity. Examples of an oxide semiconductor having crystallinity include a CAAC (c-axis-aligned crystalline)-OS and an nc (nanocrystalline)-OS. When an oxide semiconductor having crystallinity is used, a highly reliable semiconductor device can be provided.

Note that an OS transistor is preferably a vertical transistor in which a source electrode and a drain electrode are positioned at different heights. In the vertical transistor, a current flows in the height direction (Z direction) in a channel formation region of a semiconductor layer. In other words, the channel length direction can be regarded as having a component of the height direction (vertical direction). Thus, the above-described vertical transistor can also be referred to as a VFET (Vertical Field Effect Transistor), a vertical-channel transistor, a vertical-channel-type transistor, a vertical-type transistor, or the like.

In a vertical transistor, a source region, a channel formation region, and a drain region can at least partly overlap in a top view, enabling a smaller occupied area (footprint). Such a transistor enables reduced channel length and increased channel width, reducing on-state resistance (increasing on-state current).

A vertical transistor can increase the storage density as compared with a lateral transistor (also referred to as a planar structure or a planar type) in which a source electrode and a drain electrode are positioned at the same height. Vertical transistors, which have a small occupied area (footprint), enable higher storage densities in higher-level element layers. That is, in the case where the element layer 40 is stacked over the element layer 30, a structure in which vertical transistors are used as the OS transistors included in the element layer 40 is particularly effective. This structure enables a structure in which the element layers with storage densities varied in order of proximity to the element layer 20 are arranged hierarchically over the element layer 20 provided with a register and cache memories including Si transistors. For example, when the OS transistors in the element layer 30, which is close to the element layer 20, are lateral transistors and the OS transistors in the element layer 40, which is far from the element layer 20, are vertical transistors, the element layers with storage densities varied in order of proximity to the element layer 20 can be arranged hierarchically.

The element layer 30 includes the storage portion 33 provided with the memory cells 34 including OS transistors. The element layer 40 includes the storage portion 43 provided with the memory cells 44 including OS transistors. Note that the distance between the element layer 40 and the element layer 20 from which data is read is larger than the distance between the element layer 30 and the element layer 20. Thus, the element layer 40 may include an amplifier circuit for amplifying data read from the element layer 40, in addition to the storage portion 43 including the memory cells 44.

The circuit structure of the memory cell 34 provided in the storage portion 33 may be different from the circuit structure of the memory cell 44 provided in the storage portion 43. In this case, the element layers with operating speeds varied in order of proximity to the element layer 20 can be arranged hierarchically over the element layer 20. For example, a circuit structure different from that of the memory cell 34 provided in the storage portion 33 can be employed for the memory cell 44 provided in the storage portion 43. Alternatively, the transistor structure of the memory cell 34 provided in the storage portion 33 may be different from the transistor structure of the memory cell 44 provided in the storage portion 43. For example, it is possible to employ a structure in which the transistor of the memory cell 34 provided in the storage portion 33 includes a back gate electrode and the transistor of the memory cell 44 provided in the storage portion 43 does not include a back gate electrode.

The memory cells 44 provided in the storage portion 43 can be stacked across a plurality of layers. In this case, the same circuit structure may be employed across the plurality of layers among the element layers 40. This structure allows the adoption of a manufacturing process using the same photomask for the plurality of element layers. Thus, the storage portion 43 can be formed in the perpendicular direction by repeating the same manufacturing process, so that manufacturing costs can be reduced.

Note that the storage portion 43 included in the element layers 40 formed over the element layer 30 can also be designed to have different wiring intervals or different transistor sizes for the plurality of element layers 40. In such a case, specifications such as the operating speed of the storage portion 43 can vary among the plurality of element layers 40; thus, the storage portion 43 with the same area can have different storage capacities and different operating speeds.

In addition, the storage portion 33 illustrated in FIG. 1A and FIG. 1B is configured to input and output data to/from the sense amplifier circuit 21 included in the element layer 20. When the storage portion 33 is provided to overlap the region where the sense amplifier circuit 21 is provided in the element layer 20, a wiring for connecting the circuits can be shortened; thus, the operating speed can be increased as compared with the storage portion 43. The storage portion 43 illustrated in FIG. 1A and FIG. 1B is configured to input and output data to/from the sense amplifier circuit 22 included in the element layer 20. In the storage portion 43, wirings are provided to extend through the element layer 30 to the region where the sense amplifier circuit 21 is provided in the element layer 20; thus, the wirings for connecting the circuits is long. Thus, the storage portion 43 has a lower operating speed than the storage portion 33. Meanwhile, the element layer 40 can be stacked over the element layer 30, whereby the storage density (storage capacity per unit area) can be increased. Consequently, the storage portion 33 provided in the element layer 30 and the storage portion 43 provided in the element layer 40 can be hierarchical storage portions.

The storage portion 33 that excels in operating speed can be used as a cache memory, for example, a quaternary cache memory (quaternary cache, L4 cache). The storage portion 33 functioning as a cache memory can fill a performance gap between the L1 cache to the L3 cache and a main storage device. When the storage portion 33 that can be used as a large-capacity cache memory is provided above the element layer 20 provided with the L1 cache to the L3 cache, the frequency of accessing data in an external storage device (a main memory or an auxiliary storage device) due to a cache miss can be reduced, so that power efficiency can be increased. Note that the lowest-level cache can be referred to as an LLC (Last Level cache). The LLC does not require a higher operating speed than a higher-level cache, but desirably has a large storage capacity. The storage portion 33 has a high operating speed and enables long-term data retention, and thus can be suitably used as the LLC. Note that the storage portion 33 can also be used as an FLC (Final Level cache).

The storage portion 43 having a high storage density can be used as a main memory. The storage portion 43 that can be provided over the element layer 30 including the storage portion 33 functioning as a cache memory can reduce delay on a bus or the like, thereby filling a performance gap between the L4 cache and the external storage device. When the storage portion 43 that can be used as a large-capacity main memory is provided above the element layer 30 provided with the L4 cache, the frequency of accessing data in the external storage device (the main memory or the auxiliary storage device) due to a cache miss can be reduced, so that the arithmetic performance and power efficiency can be increased.

The off-state current of an OS transistor is extremely low. Accordingly, electric charge corresponding to data written to the memory cells 34 and 44 can be retained in a capacitor for a long time. In other words, data once written can be retained for a long time in the memory cells 34 and 44. Thus, the frequency of data refresh can be reduced, and power consumption of the semiconductor device 10 of one embodiment of the present invention can be reduced. Note that a storage portion including memory cells including OS transistors is referred to as an “OS memory” in some cases.

The storage portions 33 and 43 provided with the memory cells 34 and 44 each including an OS transistor can each be a DOSRAM (Dynamic Oxide Semiconductor Random Access Memory). A DOSRAM refers to a RAM including a 1T (transistor) 1C (capacitor) memory cell. A DOSRAM is a DRAM formed using an OS transistor and is a memory that temporarily stores information transmitted from the outside. A DOSRAM is a memory utilizing a low off-state current of an OS transistor. Since the DOSRAM is a 1TIC memory cell, a large storage capacity can be achieved in the storage portions 33 and 43. Furthermore, the use of an OS transistor can increase a data retention period as compared with a DRAM including a Si transistor.

The Si transistor included in the DRAM has a higher off-state current than the OS transistor. Thus, in order to reduce the off-state current of the Si transistor, the channel length needs to be large. To ensure a large channel length in a limited area, a structure in which a large channel length is secured in the depth direction of a substrate is effective; however, in this case, it is difficult to thin the substrate. In addition, the capacitance of the capacitor needs to be increased in order to retain electric charge. Thus, the height of the capacitor needs to be increased as in a trench (deep groove) structure. Consequently, the memory cell of the DRAM including the Si transistor has a large cell size in the Z direction.

In contrast, the off-state current of the OS transistor included in the DOSRAM is extremely low. Thus, the channel length does not need to be increased in order to reduce the off-state current. The thickness of one element layer 30 can be smaller than that in the DRAM. In addition, since the off-state current of the OS transistor is extremely low, the capacitance of the capacitor can be estimated to be low in the DOSRAM. For example, the capacitor can be a parallel plate capacitor instead of a trench (deep groove) capacitor. The parallel plate capacitor is manufactured more easily than a trench capacitor. This leads to a higher yield and a smaller number of manufacturing steps. Such a DOSRAM structure offering a thinner element layer, a higher yield, and a smaller number of manufacturing steps is effective particularly in the case where the DOSRAM is used in the storage portion 43 in the element layer 40 of one embodiment of the present invention.

The storage portions 33 and 43 provided with the memory cells 34 and 44 each including an OS transistor can be a NOSRAM (Nonvolatile Oxide Semiconductor Random Access Memory). A memory cell in a NOSRAM is a two-transistor (2T) or three-transistor (3T) gain cell. In the NOSRAM, data is rewritten by charge and discharge of the capacitor; hence, rewriting can be performed with no theoretical limit on the number of rewrites and at low energy. Moreover, the data operating speed can be higher in the NOSRAM than in the DOSRAM. Thus, the NOSRAM is a memory that can operate at a higher speed, has lower power consumption, and has higher rewrite endurance than the DOSRAM.

In the case where data in the NOSRAM is multilevel data with three or more levels, data capacity per memory cell can be larger than that of the DOSRAM. Furthermore, the NOSRAM can nondestructively read the written data and thus is suitable for long-time data retention. In contrast, the DOSRAM destructively reads written data and thus is suitably used for a storage portion at a level with high access frequency.

Furthermore, an OS transistor has electrical characteristics superior to those of a Si transistor in a high-temperature environment. Specifically, the on/off current ratio is large even at a high temperature higher than or equal to 125° C. and lower than or equal to 150° C.; thus, a favorable switching operation can be performed. The OS transistor operates favorably within the range from −40° C. to 190° C. In other words, the OS transistor has significantly high heat resistance. This heat resistance is higher than the heat resistance of a phase change memory (PCM) (higher than or equal to −40° C. and lower than or equal to 150° C.), the heat resistance of a resistance random access memory (ReRAM) (higher than or equal to −40° C. and lower than or equal to 125° C.), the heat resistance of a magnetoresistive random access memory (MRAM) (higher than or equal to −40° C. and lower than or equal to 105° C.), and the like.

The storage portions 33 and 43 provided with the memory cells 34 and 44 are stacked in the direction perpendicular or substantially perpendicular to the surface of the element layer 20. In other words, the element layers 30 and 40 are stacked in the direction perpendicular or substantially perpendicular to the surface of the substrate where the element layer 20 is provided. With this structure, the number of memory cells 34 and 44 provided per unit area can be increased. Thus, the storage density can be increased.

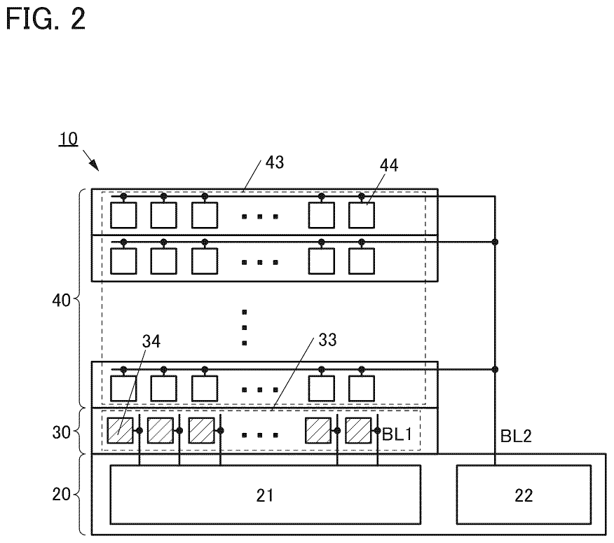

FIG. 2 is a schematic view for explaining wirings for data writing or reading that are positioned between the sense amplifier circuits 21 and 22, which are provided in the element layer 20 and include the memory cells 34, the storage portion 33, which is provided in the element layer 30 and includes the memory cells 34, and the storage portion 43, which is provided in the element layer 40 and includes the memory cells 44, in the block diagrams of FIG. 1A and FIG. 1B.

The storage portion 33 having a higher operating speed than the storage portion 43 is electrically connected to the sense amplifier circuit 21 through a wiring BL1. The storage portion 43 having a higher storage density than the storage portion 33 is electrically connected to the sense amplifier circuit 22 through a wiring BL2. The wirings BL1 and BL2 function as bit lines for data writing and reading.

The wirings BL1 and BL2 can be arranged in the horizontal direction and the perpendicular direction of the surface of the substrate where the element layer 20 is provided. The wirings BL1 and BL2 provided to extend from the memory cells 34 and 44 included in the element layers 30 and 40 are formed of wirings arranged in the perpendicular direction of the substrate surface as well as wirings arranged in the horizontal direction, whereby the length of the wiring between the memory cell 34 and the sense amplifier circuit 21 can be different from the length of the wiring between the memory cell 44 and the sense amplifier circuit 22. Thus, the signal transmission distance between the memory cell and the sense amplifier circuit can be different between the storage portion 33 and the storage portion 43; hence, it is possible to achieve different operating speeds of the memory cell 34 and the memory cell 44 as well as a reduction in power consumption and signal delay due to a significant reduction in resistance and parasitic capacitance of the bit lines.

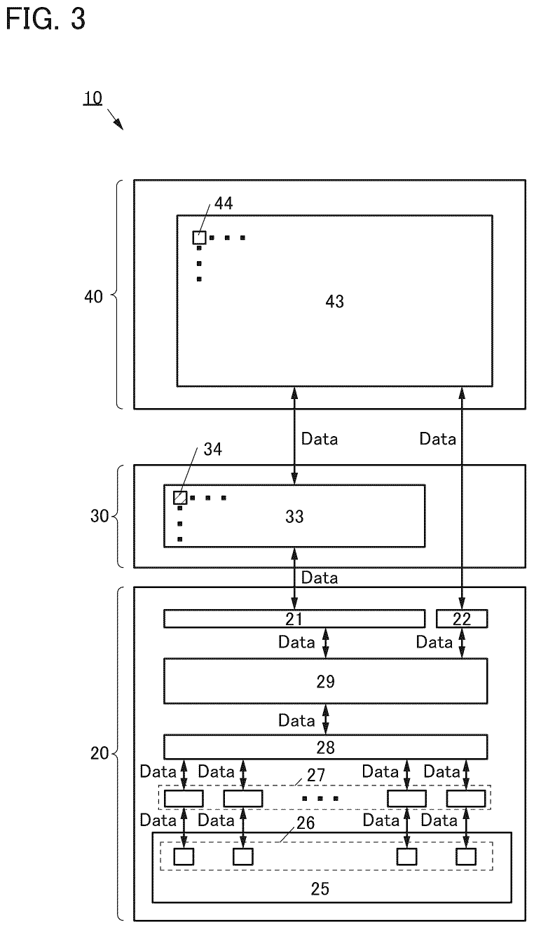

FIG. 3 is a block diagram illustrating an arithmetic portion 25, a register 26, an L1 cache 27, an L2 cache 28, and an L3 cache 29 that are provided in the element layer 20, in addition to the storage portion 43 including the memory cells 44, the storage portion 33 including the memory cells 34, and the sense amplifier circuits 21 and 22 that are included in the element layer 20, the element layer 30, and the element layer 40 described above. FIG. 3 also illustrates data Data input and output between the blocks.

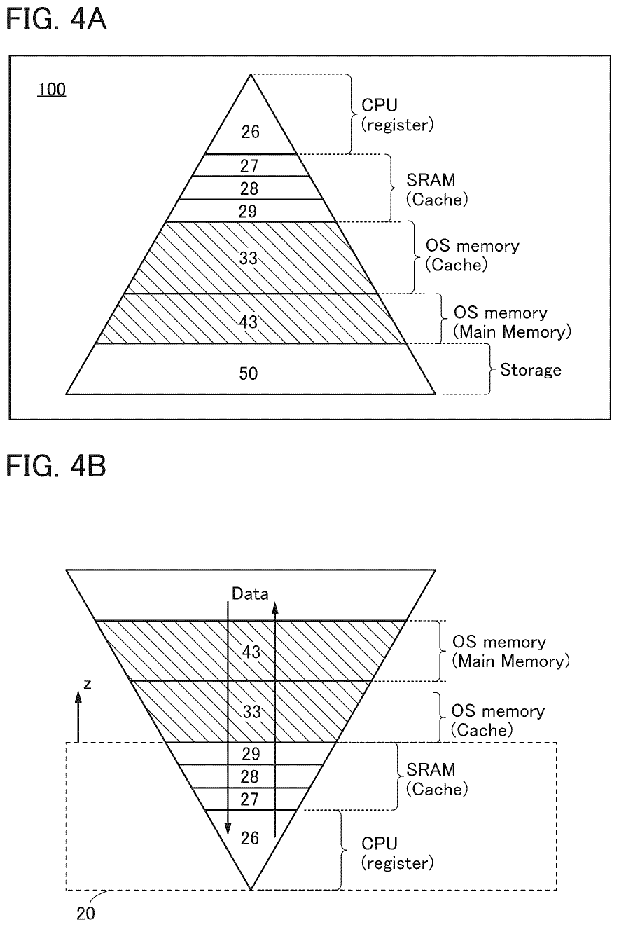

In FIG. 4A, the register 26, the L1 cache 27, the L2 cache 28, the L3 cache 29, the storage portion 33, and the storage portion 44 that are illustrated in FIG. 3 and a storage portion 50 included in an auxiliary storage device are organized hierarchically in order of operating speed and storage capacity. The diagram illustrated in FIG. 4A shows that the operating speed is higher and the storage capacity is smaller at a higher level, and the operating speed is lower and the storage capacity is larger at a lower level.

The register 26 is provided in the arithmetic portion 25 as illustrated in FIG. 3 (indicated as “CPU (registor)” in the diagram). The L1 cache 27, the L2 cache 28, and the L3 cache 29 are provided at a position close to the arithmetic portion 25 as illustrated in FIG. 3 (indicated as “SRAM (Cache)” in the diagram). The register 26 has a high operating speed and a small storage capacity. The L1 cache 27, the L2 cache 28, and the L3 cache 29 are provided near the register 26 and are in order of decreasing operating speed and increasing storage capacity.

The storage portion 33 is provided in the element layer 30 close to the element layer 20 provided with the L3 cache 29 (indicated as “OS memory (Cache)” in the diagram). The storage portion 43 is provided in the element layer 40 close to the element layer 30 provided with the storage portion 33 (indicated as “OS memory (Main Memory)” in the diagram). The storage portion 50 included in the auxiliary storage device is a storage portion provided outside the semiconductor device 10. Examples of the auxiliary storage device include a flash memory, a hard disk drive, and a solid state drive, which are storage-class memories.

In an arithmetic processing system 100, a storage portion at a higher level is required to operate at a higher speed. Moreover, a storage portion at a lower level is required to have a larger capacity and a higher density (or a smaller area per bit). For example, the storage portion 33 is closer to the arithmetic portion than the storage portion 43 is, and thus needs high-speed operation. Meanwhile, the storage portion 43 does not need high-speed operation equivalent to that of the storage portion 33, but is required to have a larger capacity and a smaller area per bit than the storage portion 33.

In the semiconductor device according to one embodiment of the present invention, the storage portion 33 functioning as a cache memory is provided between the main memory and the L3 cache 29, whereby the physical distance between the main memory and the L3 cache 29 can be shortened. Moreover, in the semiconductor device according to one embodiment of the present invention, the storage portion 43 functioning as a main memory is provided over the storage portion 33 functioning as a cache memory, whereby the physical distance between the storage portion 43 and the storage portion 33 can be shortened. Thus, a gap in data read and write latency can be reduced.

As illustrated in FIG. 4B, the semiconductor device according to one embodiment of the present invention can have a structure in which the storage portions 33 and 43 having different operating speeds or different storage capacities are stacked in the z direction (the direction perpendicular to the substrate where the element layer 20 is provided (the z direction)) and data (Data) can be input and output through the storage portions in the different layers. The data (Data) can be input and output using wirings between the stacked element layers; hence, parasitic capacitance or resistance of the wirings can be lowered, and an increase in power consumption due to the data input/output can be inhibited.

The semiconductor device according to one embodiment of the present invention can have a structure in which the storage portion 33 functioning as a cache memory and the storage portion 43 functioning as a main memory are stacked over the element layer 20 provided with the arithmetic portion, the cache memory, the sense amplifier circuits, and the like. As described above, the signal transmission distance between the memory cell and the sense amplifier circuit can be different between the storage portion 33 and the storage portion 43; hence, it is possible to achieve different operating speeds of the memory cell 34 and the memory cell 44 as well as a reduction in power consumption and signal delay due to a significant reduction in resistance and parasitic capacitance of the bit lines. Thus, the structure of one embodiment of the present invention can fill the performance gap between the L1 cache to the L3 cache and the main storage device and the performance gap between the L4 cache and the external storage device. With the storage portion 43 that can be used as a large-capacity main memory, the frequency of accessing data in the external storage device (the main memory or the auxiliary storage device) due to a cache miss can be reduced, so that power efficiency can be increased.

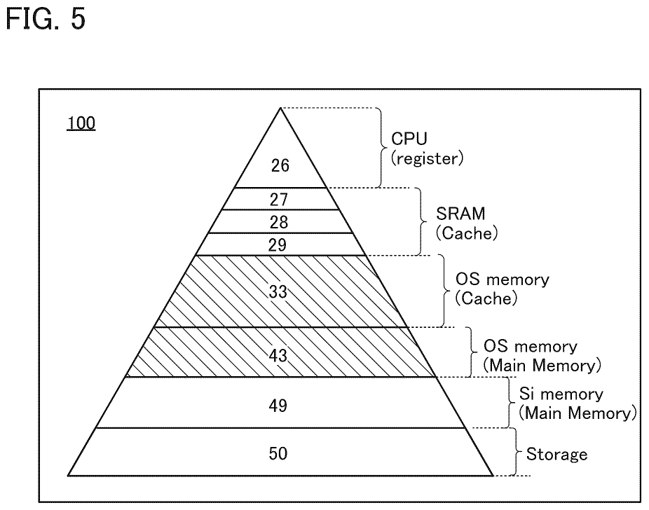

Note that a structure may be employed in which a main memory composed of Si transistors, such as a DRAM, is provided between the main memory (the storage portion 43) provided in the semiconductor device 10 and the auxiliary storage device (the storage portion 50). For example, as illustrated in FIG. 5, a storage portion 49 (indicated as “Si memory (Main Memory)” in the diagram) composed of a DRAM or the like may be provided between the storage portion 43 and the storage portion 50.

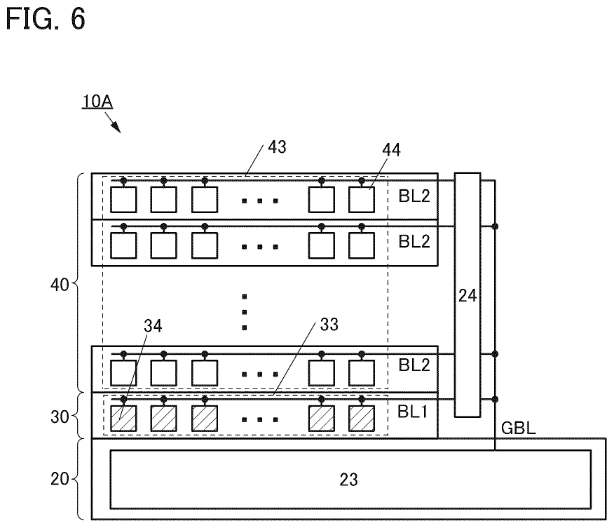

In the structure illustrated in FIG. 2, a switching circuit may be provided between the sense amplifier circuit and the wirings BL1 and BL2 in the element layers 30 and 40. For example, a switching circuit 24 may be provided as illustrated in FIG. 6. The switching circuit 24 has a function of switching electrical continuity and discontinuity between the wirings BL1 and BL2 and a wiring GBL. The wiring GBL is connected to a sense amplifier circuit 23.

The switching circuit 24 is a circuit that selects any one of the plurality of wirings BL1 and BL2 and establishes electrical continuity between the selected wiring and the wiring GBL. Thus, in the case where the same sense amplifier circuit can be used for the memory cells 34 and 44, the sense amplifier circuits 21 and 22 can be unified into the sense amplifier circuit 23. Furthermore, it is possible to reduce the number of wirings BL1 and BL2 to have electrical continuity with the wiring GBL at the time of data writing or reading, so that wiring resistance and wiring capacitance can be reduced.

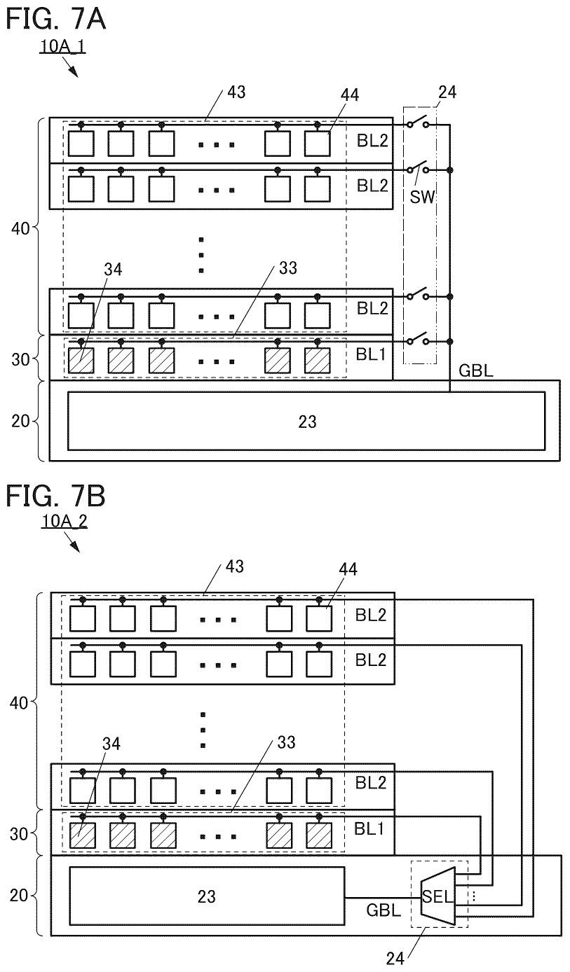

The switching circuit 24 illustrated in FIG. 6 can be composed of a plurality of switches SW as illustrated in FIG. 7A. Switching the conducting state or the non-conducting state of the switch SW enables selection of the wiring BL1 or BL2 that is to establish electrical continuity with the wiring GBL. Note that the switch SW can include an OS transistor. In this case, the switches SW can be provided in the element layer 30 and the element layer 40.

Although the plurality of switches SW are provided in the element layer 30 and the element layer 40 in FIG. 7A, they may be provided in the element layer 20. For example, as illustrated in FIG. 7B, the switching circuit 24 can be composed of a multiplexer SEL including Si transistors.

With the above structure, the element layer including a cache memory composed of OS transistors can be provided over the element layer including a cache memory composed of Si transistors, whereby the storage capacity of the cache memories can be increased. Furthermore, with a structure in which the OS memory functioning as a main memory is placed directly over the element layer including the cache memory composed of OS transistors, a semiconductor device with a small area, high arithmetic performance, and low power consumption can be provided.

Next, the description will be made on circuit structures of memory cells in a DOSRAM and a NOSRAM that can be used for the memory cell 34 of the storage portion 33 and the memory cell 44 of the storage portion 43.

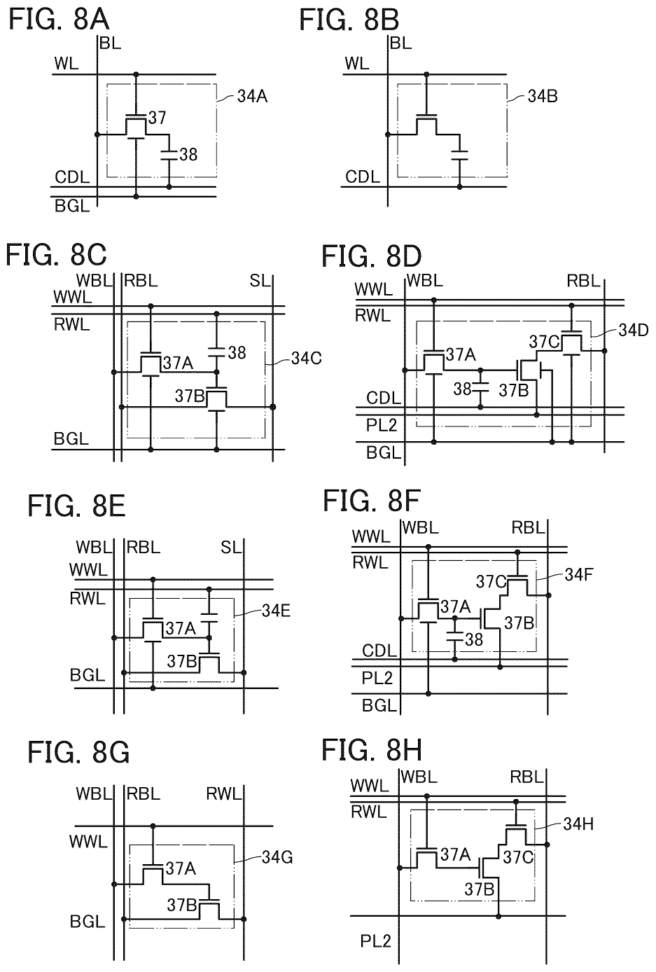

FIG. 8A to FIG. 8H are circuit diagrams each illustrating a structure example of a memory cell including an OS transistor that can be used for the above-described memory cells 34 and 44. Examples of the structure of the memory cell including an OS transistor are a DOSRAM and a NOSRAM, as described above.

FIG. 8A illustrates an example of a 1T1C DOSRAM memory cell that can be used as the memory cells 34 and 44. A memory cell 34A illustrated in FIG. 8A is electrically connected to a wiring WL, a wiring BL, a wiring CDL functioning as a capacitor line, and a wiring BGL functioning as a wiring for supplying a back gate voltage. The memory cell 34A includes a transistor 37 and a capacitor 38. A back gate of the transistor 37 is electrically connected to the wiring BGL.

The transistor 37 is an OS transistor. The off-state current of an OS transistor is extremely low. Thus, the memory cell 34A can reduce the frequency of data refresh. Thus, power required for data retention can be reduced.

FIG. 8B illustrates another structure example of a 1T1C DOSRAM memory cell. A memory cell 34B illustrated in FIG. 8B is different from the memory cell 34A illustrated in FIG. 8A in that the transistor 37 is an OS transistor without a back gate.

FIG. 8C illustrates an example of a NOSRAM memory cell of a 2-transistor (2T) gain cell that can be used as the memory cells 34 and 44. A memory cell 34C illustrated in FIG. 8C includes transistors 37A and 37B and the capacitor 38. Note that the capacitor 38 included in the memory cell of the NOSRAM can be omitted by utilizing parasitic capacitance such as gate capacitance of the transistor. The transistor 37A is a write transistor and the transistor 37B is a read transistor. Back gates of the transistors 37A and 37B are electrically connected to the wiring BGL.

Since an OS transistor serves as the write transistor, electric charge corresponding to data can be retained continuously by turning off the write transistor. Thus, the memory cell 34C does not consume power for data retention. Accordingly, the memory cell 34C can function as a memory cell with low power consumption that can retain data for a long time.

Other structure examples of memory cells used for a NOSRAM are described with reference to FIG. 8D to FIG. 8G.

A memory cell 34D illustrated in FIG. 8D is a 3T gain cell and includes transistors 37A, 37B, and 37C and the capacitor 38. The transistors 37A, 37B, and 37C are a write transistor, a read transistor, and a selection transistor, respectively. Back gates of the transistors 37A, 37B, and 37C are electrically connected to the wiring BGL. The memory cell 34D is electrically connected to wirings RWL and WWL, wirings RBL and WBL, the wiring CDL, and a power supply line PL2. For example, a voltage GND (low-level-side power supply voltage) is input to the wiring CDL and the wiring PL2.

FIG. 8E illustrates another structure example of a 2T gain cell. A memory cell 34E illustrated in FIG. 8E is different from the memory cell 34C illustrated in FIG. 8C in that the read transistor is an OS transistor without a back gate.

FIG. 8F illustrates another structure example of a 3T gain cell. A memory cell 34F illustrated in FIG. 8F is different from the memory cell 34D illustrated in FIG. 8D in that a read transistor and a selection transistor are each an OS transistor without a back gate.

FIG. 8G illustrates another structure example of a 2T gain cell. A memory cell 34G illustrated in FIG. 8G is different from the memory cell 34C illustrated in FIG. 8C in that the transistors 37A and 37B are each an OS transistor without a back gate and the capacitor 38 is omitted.

FIG. 8H illustrates another structure example of a 3T gain cell. A memory cell 34H illustrated in FIG. 8H is different from the memory cell 34D illustrated in FIG. 8D in that the transistors 37A, 37B, and 37C are each an OS transistor without a back gate and the capacitor 38 is omitted.

In the above-described gain cells, a bit line serving as both the wiring RBL and the wiring WBL can alternatively be provided.

In the case where the memory cells 34 and 44 are a DOSRAM or a NOSRAM, the wirings (the wirings WL and WWL in FIG. 8A to FIG. 8H) connected to gates of the transistors serving as access transistors (the transistors 37 and 37A in FIG. 8A to FIG. 8H) can be supplied with a voltage that turns off the transistors, and the other portions can be power gated. With this structure, the supply of power supply voltage can be stopped while data is stored in the memory cells 34 and 44.

Note that in the case where any of the memory cells 34A to 34H described with reference to FIG. 8A to FIG. 8H is used as the memory cell 34 included in the element layer 30 and the memory cell 44 included in the element layer 40, which are described with reference to FIG. 1A to FIG. 3, the memory cell 34 and the memory cell 44 are preferably memory cells with different circuit structures or memory cells with different transistor structures.

For example, it is preferable that the memory cell 34 included in the storage portion 33 functioning as a cache memory, which is described with reference to FIG. 1A to FIG. 3, be a DOSRAM memory cell including a back gate that is advantageous in controlling electrical characteristics such as threshold voltage, and the memory cell 44 included in the storage portion 43 functioning as a main memory be a DOSRAM memory cell without a back gate that is advantageous in increasing the density of storage capacity.

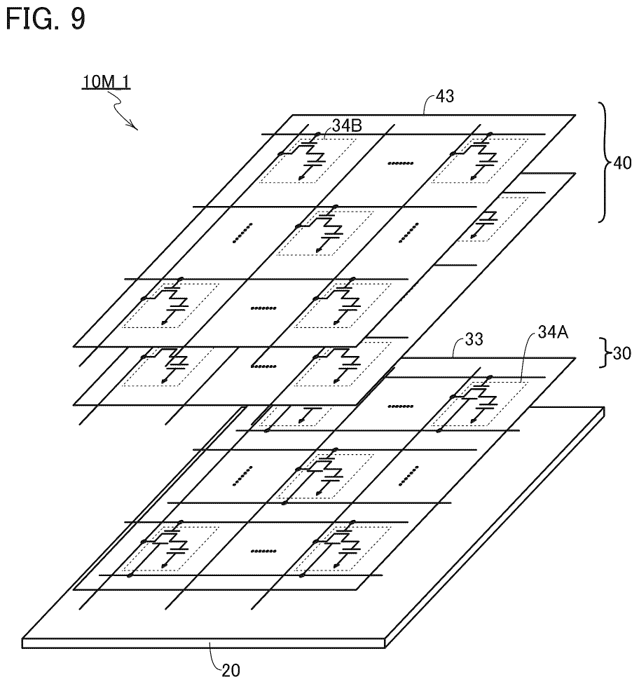

FIG. 9 is a diagram illustrating a structure example of a semiconductor device 10M_1 in which memory cells employing different transistor structures are used in the element layers 30 and 40 positioned in different layers. In FIG. 9, the memory cell 34A, which is the DOSRAM memory cell described with reference to FIG. 8A, is used in the storage portion 33 included in the element layer 30 provided over the element layer 20. That is, the transistor 37 described with reference to FIG. 8A, which includes a back gate and is advantageous in controlling electrical characteristics such as threshold voltage, is used in the storage portion 33 in the element layer 30. In the semiconductor device employing this structure, excellent transistor characteristics can be obtained in the storage portion 33 functioning as a cache memory.

Note that the storage portion 33 provided in the element layer 30 further preferably employs a DOSRAM using the above-described planar transistor. A DOSRAM using a planar transistor employs a structure including a back gate more easily than in the case of using a vertical transistor; thus, a semiconductor device with excellent transistor characteristics can be obtained.

In FIG. 9, the memory cell 34B, which is the DOSRAM memory cell described with reference to FIG. 8B, is used in the storage portion 43 included in the element layer 40 provided over the element layer 30. That is, the transistor 37 without a back gate that is described with reference to FIG. 8B and is advantageous in increasing the memory cell density is used in the storage portion 43 in the element layer 40. In the semiconductor device employing this structure, the storage portion 33 functioning as a cache memory can have the increased memory cell density.

Note that the storage portion 43 provided in the element layer 40 further preferably employs a DOSRAM using the above-described VFET. For example, when the storage portion 43 corresponding to the main memory is composed of the DOSRAM using the VFET, the memory cell density can be further increased.

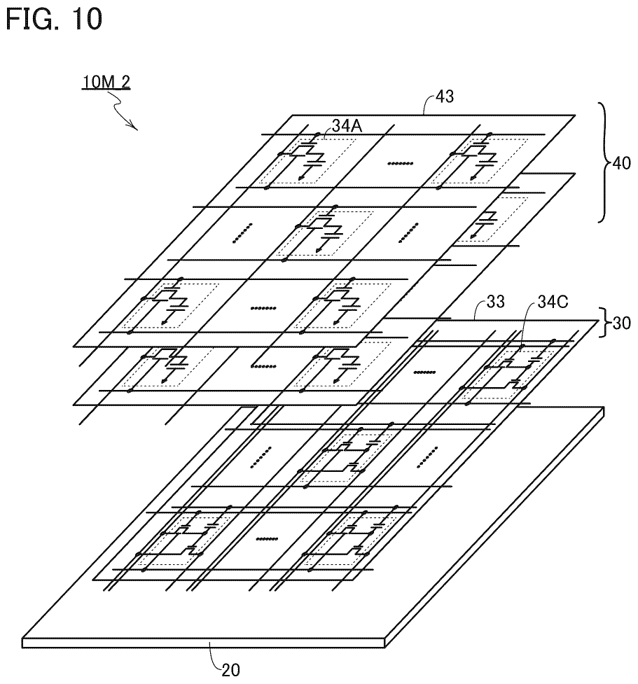

FIG. 10 is a diagram illustrating a structure example of a semiconductor device 10M_2 in which memory cells employing different transistor structures are used in the element layers 30 and 40 positioned in different layers and which has a structure different from that in FIG. 9. In FIG. 10, the transistor 37 described with reference to FIG. 8A, which includes a back gate and is advantageous in controlling electrical characteristics such as threshold voltage, is used in the storage portion 33 included in the element layer 30 provided over the element layer 20. In the semiconductor device employing this structure, excellent transistor characteristics can be obtained in the storage portion 33 functioning as a cache memory.

In the structure examples illustrated in FIG. 9 and FIG. 10, the storage portion 33 can be used as a cache memory owing to the increased operating speed. Furthermore, the storage portion 43 provided in the upper layer of the storage portion 33 can expand the level of the main memory (the hatched level in FIG. 4A) owing to the increased memory cell density. That is, when an OS memory is used as a storage portion at the level of the cache memory or a higher level, the semiconductor device 10 in which the arithmetic portion, the main memory, and the cache memory are integrated can be obtained, and a hierarchy of the storage portions different from the conventional one can be provided.

The structure of the semiconductor device 10 in which the arithmetic portion, the main memory, and the cache memory are integrated allows a reduction in size of a connection wiring and the like, as compared with a technique in which a storage portion and an arithmetic portion are bonded to each other with the use of a through electrode such as a TSV. Thus, the amount of data to be accessed between the storage portions, such as the arithmetic portion, the main memory, and the cache memory, can be increased. That is, the bandwidth of the memory (storage portion) (which is also referred to as memory bandwidth) can be increased. The bandwidth refers to the data transfer volume per unit time. The structure of the semiconductor device 10 can increase one or both of the bandwidth of the memory and access latency. Access latency refers to time between data access and start of data transmission.

This embodiment can be implemented in combination with the other embodiments described in this specification as appropriate.

### Embodiment 2

This embodiment will describe specific structure examples of the circuits included in the semiconductor device described in the above embodiment. This embodiment will describe a structure example of a semiconductor device in which an element layer provided with a storage portion including memory cells is stacked over an element layer including a sense amplifier circuit.

### Structure Example of Semiconductor Device

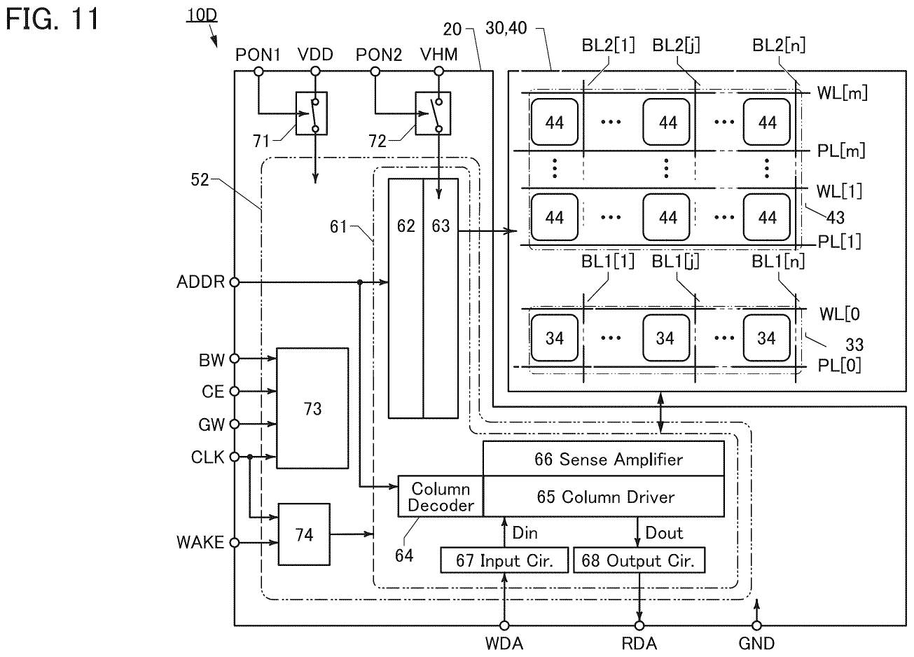

FIG. 11 is a block diagram illustrating a structure example of a semiconductor device 10D according to one embodiment of the present invention. The semiconductor device 10D illustrated in FIG. 11 includes the element layer 20, the element layer 30, and the stacked element layers 40.

Elements such as OS transistors and capacitors included in the element layer 30 and the element layers 40 form memory cells. FIG. 11 illustrates an example in which the memory cells 34 included in the storage portion 33 are arranged in a matrix of one row and n columns (n is an integer greater than or equal to 2) and the memory cells 44 included in the storage portion 43 are arranged in a matrix of m rows and n columns (n is an integer greater than or equal to 2) in the element layer 30 and the element layers 40.

FIG. 11 shows, as an example, m wirings WL extending in the row direction, m wirings PL extending in the row direction, and n wirings BL1 and n wirings BL2 extending in the column direction. In this embodiment and the like, the wiring WL, for example, is denoted as a wiring WL[1] or the like with an added ordinal number to indicate that the memory cell 34 and the memory cell 44 are connected to different combinations of wirings.

The wirings BL1 and BL2 function as bit lines for data writing and reading. The wiring WL functions as a word line for controlling the on or off state (conducting state or non-conducting state) of an access transistor functioning as a switch. The wiring PL has a function of a constant potential line connected to a capacitor. Note that a wiring CL (not illustrated) can be separately provided as a wiring for transmitting a back gate potential.

The memory cells 34 and 44, which are included in the element layer 30 and the element layer 40, respectively, are connected to a sense amplifier circuit 66 (Sense Amplifier) through the wiring BL1 or BL2. The sense amplifier circuit 66 is a circuit that can be used as the sense amplifier circuit 21 or the sense amplifier circuit 22 described in Embodiment 1.

The wirings BL can be arranged in the horizontal direction and the perpendicular direction of the surface of the substrate where the element layer 20 is provided. The wirings BL1 and BL2 provided to extend from the memory cells 34 and 44 included in the element layers 30 and 40 are formed of wirings arranged in the perpendicular direction of the substrate surface as well as wirings arranged in the horizontal direction, whereby the length of the wiring between the element layer 30 and the sense amplifier circuit 66 can be different from the length of the wiring between the element layer 40 and the sense amplifier circuit 66. Thus, the signal transmission distance between the memory cell and the sense amplifier can be shortened; hence, it is possible to achieve different operating speeds of the memory cell 34 and the memory cell 44 as well as a reduction in power consumption and signal delay due to a significant reduction in resistance and parasitic capacitance of the bit lines. As a result, the operating speed of the storage portion 33 and the storage capacity of the storage portion 43 can be increased.

The element layer 20 includes a PSW 71 (power switch), a PSW 72, and a peripheral circuit 52. The peripheral circuit 52 includes a driver circuit 61, a control circuit 73, and a voltage generation circuit 74. The circuits included in the element layer 20 are circuits including Si transistors. The description of FIG. 11 shows the structure in which the peripheral circuit 52 is provided to be shared by the memory cells 34 included in the storage portion 33 and the memory cells 44 included in the storage portion 43; however, another structure may be employed. For example, a structure may be employed in which the peripheral circuit 52 is provided for the memory cells 34 included in the storage portion 33 and another peripheral circuit is provided for the memory cells 44 included in the storage portion 43.

In the semiconductor device 10D, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PONI and the signal PON2 are power gating control signals. Note that the signal PONI and the signal PON2 may be generated in the control circuit 73.

The control circuit 73 is a logic circuit having a function of controlling the overall operation of the semiconductor device 10D. For example, the control circuit performs logical operations on the signal CE, the signal GW, and the signal BW to determine an operation mode (e.g., writing operation or reading operation) of the semiconductor device 10D. Alternatively, the control circuit 73 generates a control signal for the driver circuit 61 so that the operation mode is executed.

The voltage generation circuit 74 has a function of generating a negative voltage. The signal WAKE has a function of controlling the input of the signal CLK to the voltage generation circuit 74. For example, when an H-level signal is supplied as the signal WAKE, the signal CLK is input to the voltage generation circuit 74, and the voltage generation circuit 74 generates a negative voltage.

The driver circuit 61 is a circuit for writing and reading data to/from the memory cells 34 and 44. The driver circuit 61 includes the above-described sense amplifier circuit 66 in addition to a row decoder 62, a column decoder 64, a row driver 63, a column driver 65, an input circuit 67 (Input Cir.), and an output circuit 68 (Output Cir.).

The row decoder 62 and the column decoder 64 have a function of decoding the signal ADDR. The row decoder 62 is a circuit for specifying a row to be accessed, and the column decoder 64 is a circuit for specifying a column to be accessed. The row driver 63 has a function of selecting the wiring WL specified by the row decoder 62. The column driver 65 has a function of writing data to the memory cells 34 and 44, a function of reading data from the memory cells 34 and 44, a function of retaining the read data, and the like.

The input circuit 67 has a function of retaining the signal WDA. Data retained by the input circuit 67 is output to the column driver 65. Data output from the input circuit 67 is data (Din) to be written to the memory cells 34 and 44. Data (Dout) read from the memory cells 34 and 44 by the column driver 65 is output to the output circuit 68. The output circuit 68 has a function of retaining Dout. Moreover, the output circuit 68 has a function of outputting Dout to the outside of the semiconductor device 10D. Data output from the output circuit 68 is the signal RDA.

The PSW 71 has a function of controlling the supply of VDD to the peripheral circuit 52. The PSW 72 has a function of controlling the supply of VHM to the row driver 63. Here, in the semiconductor device 10D, a high power supply voltage is VDD and a low power supply voltage is GND (a ground potential). In addition, VHM is a high power supply voltage used to set a word line at a high level and is higher than VDD. The on/off state of the PSW 71 is controlled by the signal PON1, and the on/off state of the PSW 72 is controlled by the signal PON2. The number of power domains to which VDD is supplied is one in the peripheral circuit 52 in FIG. 11 but can be more than one. In that case, a power switch is provided for each power domain.

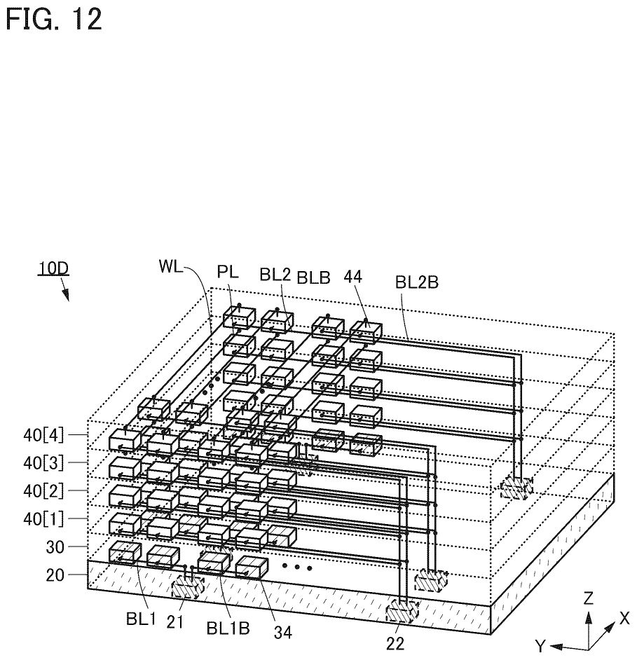

The element layers 30 and 40 can be provided over the element layer 20 to overlap the element layer 20. FIG. 12 is a perspective view of the semiconductor device 10D in which the element layer 30 and four element layers 40[1] to 40[4] (m=4) are provided over the element layer 20 to overlap the element layer 20.

In FIG. 12, the element layer 40 provided in the first layer is denoted as the element layer 40[1], the element layer 40 provided in the second layer is denoted as the element layer 40[2], and the element layer 40 provided in the fourth layer is denoted as the element layer 40[4]. FIG. 12 also shows the wiring WL and the wiring PL provided to extend in the X direction and the wirings BL1 and BL2 and wirings BL1B and BL2B provided to extend in the Y direction and the Z direction (the direction perpendicular to the surface of the substrate where the driver circuit is provided). The wirings BL1B and BL2B are inverted bit lines. For easy viewing of the drawing, some of the wirings WL and the wirings PL included in the element layer 30 are not illustrated.

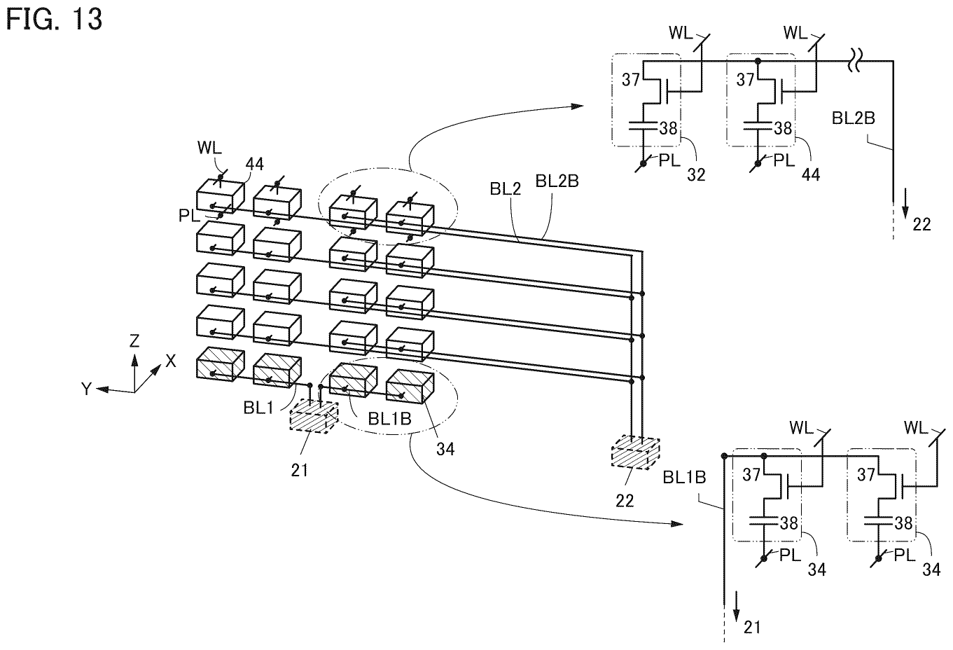

FIG. 13 is a schematic view illustrating a structure example of the memory cells 34 and 44 that are included in the element layer 30 and the element layers 40[1] to 40[4] and connected to the wirings BL1 and BL2 and the wirings BL1B and BL2BB in FIG. 12 and the sense amplifier circuits 21 and 22 connected to the wirings BL1 and BL2 and the wirings BL1B and BL2B.

FIG. 13 illustrates an example of a circuit structure of the memory cells 34 and 44 connected to the wirings BL1B and BL2BB. When having the same circuit structure, the memory cells 34 and 44 each include the transistor 37 and the capacitor 38 as illustrated in FIG. 13. As for the transistor 37, the capacitor 38, and the wirings (e.g., BL and WL), for example, the wiring BL[1] and the wiring WL[1] are referred to as the wiring BL and the wiring WL in some cases.

In each of the memory cells 34 and 44, one of a source and a drain of the transistor 37 is connected to the wiring BL. The other of the source and the drain of the transistor 37 is connected to one electrode of the capacitor 38. The other electrode of the capacitor 38 is connected to the wiring PL. A gate of the transistor 37 is connected to the wiring WL.

The wiring PL is a wiring for supplying a fixed potential for retaining the potential of the capacitor 38. When the plurality of wirings PL are connected to each other to be provided as one wiring, the number of wirings can be reduced.

In one embodiment of the present invention, OS transistors are provided in stacked layers and a wiring functioning as a bit line is provided in the direction perpendicular to the surface of the substrate where the element layer 20 is provided. In addition, the transistors 37 and the capacitors included in the memory cells 34 and 44 are arranged in the direction perpendicular to the surface of the substrate where the element layer 20 is provided. When the elements and the wirings are provided in the direction perpendicular to the surface of the substrate, the length of the wirings between the element layers can be shortened and the density of elements provided per unit area can be increased. Thus, the signal transmission distance between the memory cell and the sense amplifier can be shortened; hence, it is possible to achieve different operating speeds of the memory cell 34 and the memory cell 44 as well as a reduction in power consumption and signal delay due to a significant reduction in resistance and parasitic capacitance of the bit lines. As a result, the operating speed of the storage portion 33 and the storage capacity of the storage portion 43 can be increased.

### Structure Examples of Memory Cells 34 and 44 and Sense Amplifier Circuit 66

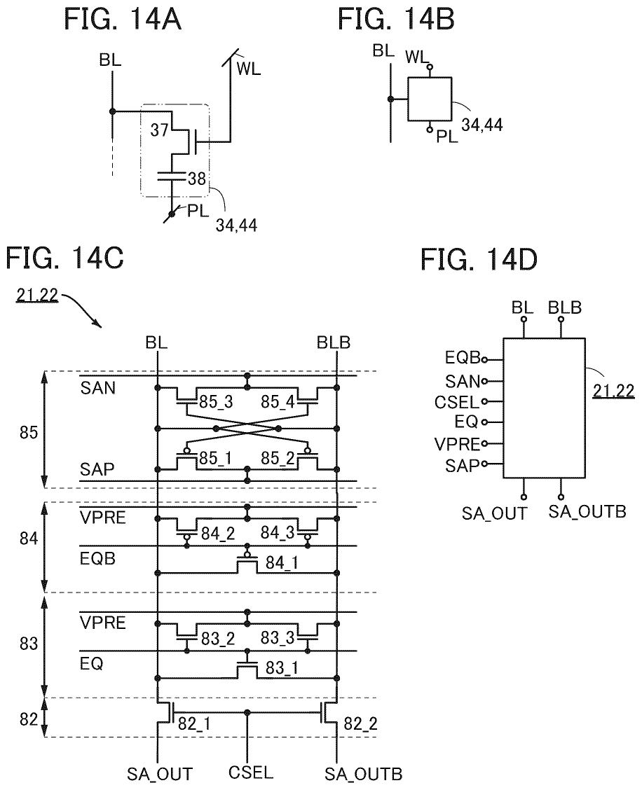

FIG. 14A and FIG. 14B are a circuit diagram corresponding to the above-described memory cells 34 and 44 and a diagram illustrating a circuit block corresponding to the circuit diagram. As illustrated in FIG. 14A and FIG. 14B, the memory cells 34 and 44 are sometimes illustrated as a block in the drawing and the like. Note that the same can be applied to the case where the wiring BL (corresponding to the wirings BL1 and BL2) illustrated in FIG. 14A and FIG. 14B is replaced with a wiring BLB (corresponding to the wirings BL1B and BL2B).

FIG. 14C and FIG. 14D are a circuit diagram of the sense amplifier circuits 21 and 22 corresponding to the above-described sense amplifier circuit 66 and a diagram illustrating a circuit block corresponding to the circuit diagram. The sense amplifier circuits 21 and 22 include a switch circuit 82, a precharge circuit 83, a precharge circuit 84, and an amplifier circuit 85. In addition to the wiring BL and the wiring BLB, a wiring SA_OUT and a wiring SA_OUTB that output a read signal are shown.

The switch circuit 82 includes, for example, n-channel transistors 82_1 and 82_2, as illustrated in FIG. 14C. The transistors 82_1 and 82_2 switch electrical continuity between the wiring SA_OUT and the wiring BL and between the wiring SA_OUTB and the wiring BLB in response to a signal CSEL; the wiring SA_OUT and the wiring SA_OUTB form a wiring pair and the wiring BL and the wiring BLB form a wiring pair.

The precharge circuit 83 is composed of n-channel transistors 83_1 to 83_3 as illustrated in FIG. 14C. The precharge circuit 83 is a circuit for precharging the wiring BL and the wiring BLB to an intermediate potential VPRE corresponding to half of the potential VDD in response to a signal EQ.

The precharge circuit 84 is composed of p-channel transistors 84_1 to 84_3 as illustrated in FIG. 14C. The precharge circuit 84 is a circuit for precharging the wiring BL and the wiring BLB to the intermediate potential VPRE, which corresponds to half of the potential VDD, in response to a signal EQB.

The amplifier circuit 85 is composed of p-channel transistors 85_1 and 85_2 and n-channel transistors 85_3 and 85_4 that are connected to a wiring SAP or a wiring SAN, as illustrated in FIG. 14C. The wiring SAP or the wiring SAN is a wiring having a function of supplying VDD or VSS. The transistors 85_1 to 85_4 are transistors that form an inverter loop.

FIG. 14D is a diagram illustrating a circuit block corresponding to the sense amplifier circuits 21 and 22 described with reference to FIG. 14C and the like. As illustrated in FIG. 14D, the sense amplifier circuits 21 and 22 are sometimes illustrated a block in the drawing and the like.

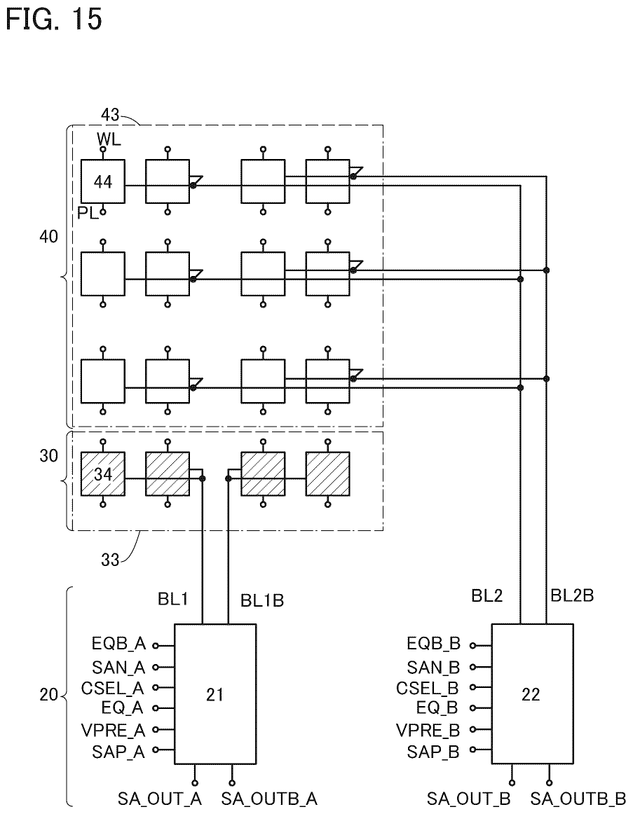

FIG. 15 is a circuit diagram of the semiconductor device 10D in FIG. 12. In FIG. 15, the circuit blocks illustrated in FIG. 14A to FIG. 14D are used.

As illustrated in FIG. 15, the storage portion 33 provided in the element layer 30 and the storage portion 43 provided in the element layer 40 include the memory cells 34 and 44. The memory cells 34 and 44 illustrated in FIG. 15 are connected to a pair of wirings BLI and BL1B or a pair of wirings BL2 and BL2B, for example. The memory cell 34 connected to the wiring BL1 and the wiring BL1B and 44 connected to the wiring BL2 and the wiring BL2B are memory cells subjected to data writing or reading.

The wiring BL1 and the wiring BL1B are connected to the sense amplifier circuit 21, and the wiring BL2 and the wiring BL2B are connected to the sense amplifier circuit 22. The sense amplifier circuit 21 and the sense amplifier circuit 22 can read data in response to various signals described with reference to FIG. 14C.

The configurations, structures, methods, and the like described in this embodiment can be used in an appropriate combination with any of the configurations, structures, methods, and the like described in the other embodiments and the like.

### Embodiment 3

In this embodiment, cross-sectional structure examples of stacked element layers that include OS transistors and can be used for a semiconductor device and the like will be described. In this embodiment, examples of a schematic cross-sectional view applicable to a circuit structure of a DOSRAM or a NOSRAM will be described.

### DOSRAM Structure Example 1

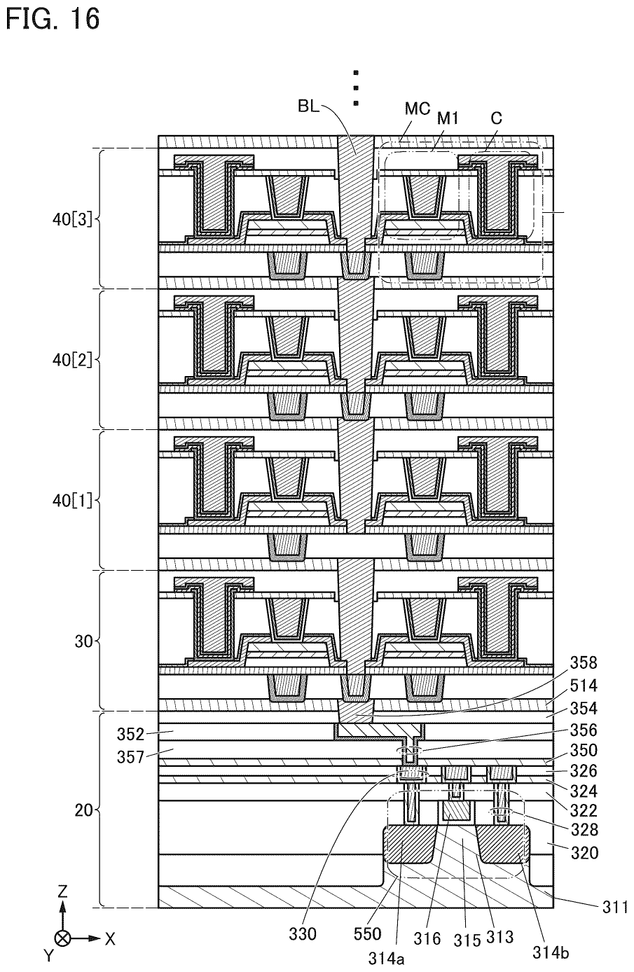

FIG. 16 illustrates a cross-sectional structure example of the case of using a DOSRAM circuit structure. In the example illustrated in FIG. 16, the element layer 30 and the element layer 40[1] to the element layer 40[3] are stacked over the element layer 20.

FIG. 16 illustrates a transistor 550 included in the element layer 20 as an example. The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

Note that the transistor 550 may be either a p-channel transistor or an n-channel transistor.

The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, a semiconductor material such as silicon including an element that imparts n-type conductivity, such as arsenic or phosphorus, or an element that imparts p-type conductivity, such as boron, or a conductive material such as a metal material, an alloy material, or a metal oxide material can be used.

The transistor 550 may be formed using an SOI (silicon on Insulator) substrate or the like.

The transistor 550 illustrated in FIG. 16 is an example and the structure is not limited thereto; an appropriate transistor can be used depending on a circuit structure, a driving method, or the like.

A wiring layer provided with an interlayer film, a wiring, a plug, and the like may be provided between the element layer 20 and the element layer 30, between the element layer 30 and the element layer 40, or between a k-th element layer 40 and a (k+1)th element layer 40. Note that in this embodiment and the like, the k-th element layer 40 may be referred to as an element layer 40[k], and the (k+1)th element layer 40 may be referred to as an element layer 40[k+1]. Here, k is an integer greater than or equal to 1 and less than or equal to N. In addition, in this embodiment and the like, the solutions of “k+a (a is an integer greater than or equal to 1)” and “k−a” are each an integer greater than or equal to 1 and less than or equal to N.

A plurality of wiring layers can be provided in accordance with the design. Furthermore, in this specification and the like, a wiring and a plug electrically connected to the wiring may be a single component. That is, part of a conductor functions as a wiring in some cases, and part of a conductor functions as a plug in other cases.

For example, an insulator 320, an insulator 322, an insulator 324, and an insulator 326 are stacked in this order over the transistor 550 as interlayer films. A conductor 328 and the like are embedded in the insulator 320 and the insulator 322. A conductor 330 and the like are embedded in the insulator 324 and the insulator 326. Note that the conductor 328 and the conductor 330 each function as a contact plug or a wiring.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

An insulator functioning as an interlayer film may function as a planarization film that covers an uneven shape thereunder. For example, the top surface of the insulator 320 may be planarized by planarization treatment using a chemical mechanical polishing (CMP) method or the like to increase planarity.

For the insulator 324, it is preferable to use a film having a barrier property that prevents diffusion of hydrogen, impurities, or the like from the substrate 311, the transistor 550, or the like into a region where transistors 500 included in the element layer 30 and the element layer 40[1] to the element layer 40[3] are provided.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Thus, a film that inhibits diffusion of hydrogen is preferably provided between the transistor 500 and the transistor 550. The film that inhibits hydrogen diffusion is specifically a film from which a small amount of hydrogen is released.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with a low permittivity is used for an interlayer film, parasitic capacitance generated between wirings can be reduced.

A wiring layer may be provided over the insulator 326 and the conductor 330. For example, in FIG. 16, an insulator 350, an insulator 357, an insulator 352, and an insulator 354 are stacked in this order over the insulator 326 and the conductor 330. A conductor 356 is formed in the insulator 350, the insulator 357, and the insulator 352. The conductor 356 functions as a contact plug or a wiring.

As a material for each of the plugs and wirings (the conductor 328, the conductor 330, and the like), a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

An insulator 514 included in the element layer 30 is provided over the insulator 354. A conductor 358 is embedded in the insulator 514 and the insulator 354. The conductor 358 functions as a contact plug or a wiring. For example, the wiring BL and the transistor 550 are electrically connected to each other through the conductor 358, the conductor 356, the conductor 330, and the like.

For example, the insulator 350 is preferably formed using an insulator having a barrier property against hydrogen, like the insulator 324. The conductor 356 preferably includes a conductor having a barrier property against hydrogen. The conductor having a barrier property against hydrogen is formed particularly in an opening portion of the insulator 350 having a barrier property against hydrogen. With this structure, the transistor 550 and the transistor 500 can be separated with the barrier layer, so that hydrogen diffusion from the transistor 550 into the transistor 500 can be inhibited.

Note that for the conductor having a barrier property against hydrogen, tantalum nitride or the like is preferably used, for example. In addition, by stacking tantalum nitride and tungsten, which has high conductivity, diffusion of hydrogen from the transistor 550 can be inhibited while the conductivity as a wiring is kept. In that case, a tantalum nitride layer having a barrier property against hydrogen is preferably in contact with the insulator 350 having a barrier property against hydrogen.

FIG. 16 illustrates an example in which two memory cells MC are electrically connected to one wiring BL in each of the element layer 30 and the element layer 40[1] to the element layer 40[3]. The memory cell MC illustrated in FIG. 16 includes a transistor MI and a capacitor C. As the transistor M1, an OS transistor can be used.

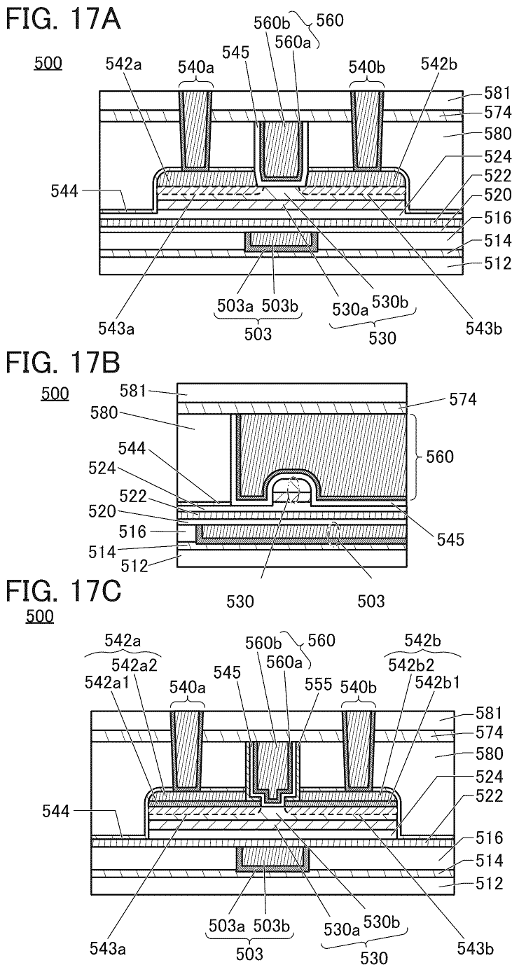

Here, an OS transistor will be described with reference to FIG. 17A to FIG. 17C. FIG. 17A and FIG. 17B are schematic cross-sectional views of the transistor 500 that can be used as the transistor M1.

As illustrated in FIG. 17A and FIG. 17B, the transistor 500 includes a conductor 503 positioned to be embedded in the insulator 514 and an insulator 516, an insulator 520 positioned over the insulator 516 and the conductor 503, an insulator 522 positioned over the insulator 520, an insulator 524 positioned over the insulator 522, an oxide 530a positioned over the insulator 524, an oxide 530b positioned over the oxide 530a, a conductor 542a and a conductor 542b positioned apart from each other over the oxide 530b, an insulator 580 that is positioned over the conductor 542a and the conductor 542b and has an opening overlapping a region between the conductor 542a and the conductor 542b, an insulator 545 positioned on the bottom surface and a side surface of the opening, and a conductor 560 positioned on the formation surface of the insulator 545.

As illustrated in FIG. 17A and FIG. 17B, an insulator 544 is preferably placed between the insulator 580 and the oxide 530a, the oxide 530b, the conductor 542a, and the conductor 542b. In addition, as illustrated in FIG. 17A and FIG. 17B, the conductor 560 preferably includes a conductor 560a provided inside the insulator 545 and a conductor 560b embedded inside the conductor 560a. Moreover, as illustrated in FIG. 17A and FIG. 17B, an insulator 574 is preferably placed over the insulator 580, the conductor 560, and the insulator 545.

Note that in this specification and the like, the oxide 530a and the oxide 530b are collectively referred to as an oxide 530 in some cases.

Note that the transistor 500 is illustrated to have a structure in which two layers, the oxide 530a and the oxide 530b, are stacked in a region where a channel is formed and its vicinity; however, the present invention is not limited thereto. For example, a single layer of the oxide 530b or a stacked-layer structure of three or more layers may be provided.

Although the conductor 560 has a stacked-layer structure of two layers in the transistor 500, the present invention is not limited thereto. For example, the conductor 560 may have a single-layer structure or a stacked-layer structure of three or more layers. The transistor 500 illustrated in FIG. 17A is an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, which results in a reduction in the area occupied by the transistor 500. Accordingly, miniaturization and higher integration of the semiconductor device can be achieved.

Since the conductor 560 is formed in the region between the conductor 542a and the conductor 542b in a self-aligned manner, the conductor 560 does not have a region overlapping the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 sometimes functions as a first gate (also referred to as top gate) electrode. The conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is positioned to be overlapped by the oxide 530 and the conductor 560. Accordingly, when a potential is applied to the conductor 560 and the conductor 503, an electric field generated from the conductor 560 and an electric field generated from the conductor 503 are connected, thereby covering the channel formation region in the oxide 530.

In this specification and the like, a transistor structure where a channel formation region is electrically surrounded by an electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure in which at least two or more surfaces (specifically, two surfaces, three surfaces, four surfaces, or the like) of a channel are covered with a gate electrode. With the Fin-type structure or the S-channel structure, resistance to a short-channel effect can be increased, that is, a transistor in which a short-channel effect is less likely to occur can be provided.

When the transistor has the S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can spread throughout the entire bulk of the oxide 530. Accordingly, the density of current flowing through the transistor can be increased, which should increase the on-state current of the transistor or increase the field-effect mobility of the transistor.

In the conductor 503, a conductor 503a is formed in contact with an inner wall of an opening in the insulator 514 and the insulator 516, and a conductor 503b is formed on the inner side. Note that although the conductor 503a and the conductor 503b are stacked in the transistor 500, the present invention is not limited thereto. For example, the conductor 503 may have a single-layer structure or a stacked-layer structure of three or more layers.

Here, for the conductor 503a, it is preferable to use a conductive material that has a function of inhibiting diffusion of impurities such as a hydrogen atom, a hydrogen molecule, a water molecule, and a copper atom (through which the impurities do not easily pass). Alternatively, it is preferable to use a conductive material that has a function of inhibiting diffusion of oxygen (e.g., at least one of an oxygen atom, an oxygen molecule, and the like) (through which oxygen does not easily pass). Note that in this specification, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In the case where the conductor 503 also functions as a wiring, a high-conductivity conductive material that includes tungsten, copper, or aluminum as its main component is preferably used for the conductor 503b. Note that although the conductor 503 is illustrated as a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator containing oxygen more than that in the stoichiometric composition is preferably used as the insulator 524 in contact with the oxide 530. Such oxygen is easily released from the film by heating. In this specification and the like, oxygen released by heating is sometimes referred to as “excess oxygen”. That is, a region including excess oxygen (also referred to as an “excess-oxygen region”) is preferably formed in the insulator 524. When such an insulator including excess oxygen is provided in contact with the oxide 530, oxygen vacancies (also referred to as Vo) in the oxide 530 can be reduced and the reliability of the transistor 500 can be increased. In the case where hydrogen enters the oxygen vacancies in the oxide 530, such defects (hereinafter sometimes referred to as VoH) serve as donors and generate electrons serving as carriers in some cases. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in the oxide semiconductor is easily transferred by a stress such as heat or an electric field; thus, a large amount of hydrogen in the oxide semiconductor might reduce the reliability of the transistor. In one embodiment of the present invention, VoH in the oxide 530 is preferably reduced as much as possible so that the oxide 530 becomes a highly purified intrinsic or substantially highly purified intrinsic oxide. In order to obtain such an oxide semiconductor with sufficiently reduced VoH, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with a sufficiently reduced amount of impurities such as VoH is used for the channel formation region of the transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸atoms/cm³, preferably greater than or equal to 1.0×10¹⁹atoms/cm³, further preferably greater than or equal to 2.0×10¹⁹ atoms/cm³ or greater than or equal to 3.0×102⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

Any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “VoH→Vo+H” occurs. Part of hydrogen generated at this time is bonded to oxygen and is removed as H₂O from the oxide 530 or an insulator in the vicinity of the oxide 530 in some cases. In other cases, part of hydrogen is gettered by the conductors 542a and 542b.

In addition, for the microwave treatment, for example, it is suitable to use an apparatus including a power supply that generates high-density plasma or an apparatus including a power supply that applies RF to the substrate side. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate ratio (O₂/(O₂+Ar)) is lower than or equal to 50 %, preferably higher than or equal to 10 % and lower than or equal to 30 %.

In the manufacturing process of the transistor 500, it is suitable to perform the heat treatment with the surface of the oxide 530 exposed. The heat treatment is performed at higher than or equal to 100° C. and lower than or equal to 450° C., further preferably higher than or equal to 350° C. and lower than or equal to 400° C., for example. Note that the heat treatment is performed in a nitrogen gas or inert gas atmosphere, or an atmosphere containing an oxidizing gas at higher than or equal to 10 ppm, higher than or equal to 1 %, or higher than or equal to 10 %. For example, the heat treatment is preferably performed in an oxygen atmosphere. Accordingly, oxygen can be supplied to the oxide 530 to reduce oxygen vacancies (Vo). The heat treatment may be performed under reduced pressure. Alternatively, the heat treatment may be performed in such a manner that heat treatment is performed in a nitrogen gas or inert gas atmosphere, and then heat treatment is performed in an atmosphere including an oxidizing gas at higher than or equal to 10 ppm, higher than or equal to 1 %, or higher than or equal to 10 % in order to compensate for released oxygen. Alternatively, the heat treatment may be performed in such a manner that heat treatment is performed in an atmosphere including an oxidizing gas at higher than or equal to 10 ppm, higher than or equal to 1 %, or higher than or equal to 10 %, and then heat treatment is successively performed in a nitrogen gas or inert gas atmosphere.

Note that oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In the case where the insulator 524 includes an excess-oxygen region, it is preferable that the insulator 522 have a function of inhibiting diffusion of oxygen (e.g., an oxygen atom, an oxygen molecule, or the like) (through which oxygen does not easily pass).

The insulator 522 preferably has a function of inhibiting diffusion of oxygen, impurities, or the like, in which case diffusion of oxygen included in the oxide 530 to the insulator 520 side is prevented.. Furthermore, the conductor 503 can be inhibited from reacting with oxygen included in the insulator 524, the oxide 530, or the like.

For the insulator 522, a single layer or stacked layers of an insulator including what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba, Sr)TiO₃ (BST) are preferably used, for example. As miniaturization and higher integration of transistors progress, a problem such as off-state current might arise because of a thinner gate insulating film. When a high-k material is used for an insulator functioning as a gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (through which oxygen does not easily pass). Aluminum oxide, hafnium oxide, an oxide containing aluminum and hafnium (hafnium aluminate), or the like is preferably used for the insulator including an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. A stack of the insulator and silicon oxide, silicon oxynitride, or silicon nitride may be used.

It is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and high relative permittivity.

Note that the transistor 500 in FIG. 17A and FIG. 17B includes the insulator 520, the insulator 522, and the insulator 524 as the second gate insulating film having a three-layer structure; however, the second gate insulating film may have a single-layer structure or a stacked-layer structure of two layers or four or more layers. In such a case, the stacked layers are not necessarily formed of the same material and may be formed of different materials.

In the transistor 500, a metal oxide functioning as an oxide semiconductor is used as the oxide 530 including the channel formation region.

The metal oxide functioning as an oxide semiconductor may be formed by a sputtering method or an ALD (Atomic Layer Deposition) method. Note that the metal oxide functioning as an oxide semiconductor is described in detail in another embodiment.

The metal oxide functioning as the channel formation region in the oxide 530 has a band gap of preferably 2 eV or more, further preferably 2.5 eV or more. The use of a metal oxide having such a wide band gap can reduce the off-state current of the transistor.

When the oxide 530 includes the oxide 530a under the oxide 530b, it is possible to inhibit diffusion of impurities into the oxide 530b from the components formed below the oxide 530a.

The oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a bonding portion of the oxide 530a and the oxide 530b. In other words, the energy level of the conduction band minimum at the bonding portion of the oxide 530a and the oxide 530b continuously changes or is continuously connected. To change the energy level gradually, the density of defect states in a mixed layer formed at the interface between the oxide 530a and the oxide 530b is preferably made low.

Specifically, when the oxide 530a and the oxide 530b include a common element (as a main component) in addition to oxygen, a mixed layer with a low density of defect states can be formed. For example, in the case where the oxide 530b is an In—Ga—Zn oxide, it is preferable to use an In—Ga—Zn oxide, a Ga—Zn oxide, gallium oxide, or the like as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including the above metal element; an alloy including a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Furthermore, a metal nitride film of tantalum nitride or the like is preferable because it has a barrier property against hydrogen or oxygen.

Although the conductor 542a and the conductor 542b have a single-layer structure in FIG. 17A, they may have a stacked-layer structure of two or more layers. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed thereover; and a three-layer structure where a molybdenum film or a molybdenum nitride film is formed, an aluminum film or a copper film is stacked over the molybdenum film or the molybdenum nitride film, and a molybdenum film or a molybdenum nitride film is formed thereover. Note that a transparent conductive material including indium oxide, tin oxide, or zinc oxide may be used.

As illustrated in FIG. 17A, a region 543a and a region 543b are sometimes formed as low-resistance regions at the interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that includes the metal included in the conductor 542a (the conductor 542b) and the component of the oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator including an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Thus, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

The insulator 544 can inhibit impurities such as water and hydrogen included in the insulator 580 from diffusing into the oxide 530b. Furthermore, oxidation of the conductors 542a and 542b due to excess oxygen included in the insulator 580 can be inhibited.

The insulator 545 functions as a first gate insulating film. Like the insulator 524, the insulator 545 is preferably formed using an insulator that includes excess oxygen and releases oxygen by heating.

Specifically, it is possible to use any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide each including excess oxygen. In particular, silicon oxide and silicon oxynitride are preferable because they are thermally stable.

When an insulator including excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

To efficiently supply excess oxygen included in the insulator 545 to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 functioning as the first gate electrode has a two-layer structure in FIG. 17A and FIG. 17B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. Alternatively, for the conductor 560a, an oxide semiconductor that can be used as the oxide 530 can be used. In that case, when the conductor 560b is deposited by a sputtering method, the conductor 560a can have a reduced electrical resistance to be a conductor. Such a conductor can be referred to as an OC (Oxide Conductor) electrode.

A conductive material containing tungsten, copper, or aluminum as its main component is preferably used for the conductor 560b. The conductor 560b also functions as a wiring and thus a conductor having high conductivity is preferably used. For example, a conductive material containing tungsten, copper, or aluminum as its main component can be used. Moreover, the conductor 560b may have a stacked-layer structure, for example, a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap the region between the conductor 542a and the conductor 542b. Accordingly, the conductor 560 is formed to be embedded in the opening of the insulator 580 and the region between the conductor 542a and the conductor 542b.

The gate length needs to be short for scaling down of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

A conductor 540a and a conductor 540b are positioned in openings formed in the insulator 581, the insulator 574, the insulator 580, and the insulator 544. The conductor 540a and the conductor 540b are provided to face each other with the conductor 560 therebetween.

In particular, aluminum oxide has an excellent blocking effect that prevents passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Thus, aluminum oxide is suitably used for a protective film of the transistor 500.

A conductor 546, a conductor 548, and the like are embedded in the insulator 520, the insulator 522, the insulator 524, the insulator 544, the insulator 580, the insulator 574, the insulator 581, an insulator 582, and an insulator 586.

The conductor 546 and the conductor 548 have functions of plugs or wirings that are connected to the transistor 500 or the transistor 550. The conductor 546 and the conductor 548 can be provided using materials similar to those for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the manufacturing steps of the transistor 500. For the insulator having a high barrier property against hydrogen or water, a material similar to that for the insulator 522 or the insulator 514 can be used, for example.

Note that the transistor that can be used in the present invention is not limited to the transistor 500 illustrated in FIG. 17A and FIG. 17B. For example, the transistor 500 having a structure illustrated in FIG. 17C may be used. The transistor 500 illustrated in FIG. 17C is different from the transistor illustrated in FIG. 17A and FIG. 17B in that an insulator 555 is used and that a stacked-layer structure is employed for the conductor 542a (a conductor 542a1 and a conductor 542a2) and the conductor 542b (a conductor 542b1 and a conductor 542b2).

The conductor 542a has a stacked-layer structure of the conductor 542a1 and the conductor 542a2 over the conductor 542a1, and the conductor 542b has a stacked-layer structure of the conductor 542b1 and the conductor 542b2 over the conductor 542b1. The conductor 542a1 and the conductor 542b1 in contact with the oxide 530b are preferably conductors that are less likely to be oxidized, such as a metal nitride. This can prevent excessive oxidation of the conductor 542a and the conductor 542b due to oxygen included in the oxide 530b. In addition, the conductor 542a2 and the conductor 542b2 are preferably conductors that have higher conductivity than the conductor 542a1 and the conductor 542b1, such as metal layers. This allows the conductor 542a and the conductor 542b to function as wirings or electrodes having high conductivity. In this manner, it is possible to provide a semiconductor device in which the conductor 542a and the conductor 542b that function as wirings or electrodes are provided in contact with the top surface of the oxide 530 functioning as an active layer.

A metal nitride is preferably used for the conductors 542a1 and 542b1. For example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542a1 and the conductor 542b1. For example, the thicknesses of the conductor 542a2 and the conductor 542b2 are preferably larger than the thicknesses of the conductor 542a1 and the conductor 542b1. For the conductor 542a2 and the conductor 542b2, a conductor that can be used for the conductor 560b can be used. The above structure can reduce the resistance of the conductor 542a2 and the conductor 542b2.

For example, tantalum nitride or titanium nitride can be used for the conductor 542al and the conductor 542b1, and tungsten can be used for the conductor 542a2 and the conductor 542b2.

As illustrated in FIG. 17C, in a cross-sectional view in the channel length direction of the transistor 500, the distance between the conductor 542al and the conductor 542b1 is shorter than the distance between the conductor 542a2 and the conductor 542b2. Such a structure allows the distance between the source and the drain to be shortened and the channel length to be shortened accordingly. Thus, the frequency characteristics of the transistor 500 can be improved. The semiconductor device that is miniaturized in this manner can have higher operating speed.

The insulator 555 is preferably an insulator that is not easily oxidized, such as a nitride. The insulator 555 is formed in contact with a side surface of the conductor 542a2 and a side surface of the conductor 542b2 and has a function of protecting the conductor 542a2 and the conductor 542b2. The insulator 555 is preferably an inorganic insulator that is not easily oxidized because it is exposed to an oxidizing atmosphere. In addition, the insulator 555 is preferably an inorganic insulator that does not easily oxidize the conductors 542a2 and 542b2 because it is in contact with the conductor 542a2 and the conductor 542b2. Thus, an insulating material having a barrier property against oxygen is preferably used for the insulator 555. For example, silicon nitride can be used for the insulator 555.

The transistor 500 illustrated in FIG. 17C is formed in the following manner: an opening is formed in the insulator 580 and the insulator 544, the insulator 555 is formed in contact with the sidewall of the opening, and then the conductor 542a1 and the conductor 542b1 are separated using a mask. Here, the opening overlaps a region between the conductor 542a2 and the conductor 542b2. The conductor 542a1 and the conductor 542b1 are formed to partly extend in the opening. Thus, in the opening, the insulator 555 is in contact with the top surface of the conductor 542a1, the top surface of the conductor 542b1, a side surface of the conductor 542a2, and a side surface of the conductor 542b2. The insulator 545 is in contact with the top surface of the oxide 530 in a region between the conductor 542a1 and the conductor 542b1.

Heat treatment is preferably performed in an oxygen-containing atmosphere after the separation into the conductor 542a1 and the conductor 542b1 and before the deposition of the insulator 545. Thus, oxygen can be supplied to the oxide 530a and the oxide 530b to reduce oxygen vacancies. In addition, when the insulator 555 is formed in contact with the side surface of the conductor 542a2 and the side surface of the conductor 542b2, the conductor 542a2 and the conductor 542b2 can be prevented from being excessively oxidized. Consequently, electrical characteristics and reliability of the transistor can be improved. Moreover, variations in electrical characteristics of transistors formed over the same substrate can be reduced.

In the transistor 500, the insulator 524 may be formed into an island shape, as illustrated in FIG. 17C. Here, the insulator 524 may be formed such that its side end portion is substantially aligned with a side end portion of the oxide 530.

In the transistor 500, the insulator 522 may be in contact with the insulator 516 and the conductor 503, as illustrated in FIG. 17C. In other words, a structure where the insulator 520 illustrated in FIG. 17A and FIG. 17B is not provided may be employed.

With the use of this structure, a semiconductor device using a transistor including an oxide semiconductor can be miniaturized or highly integrated.

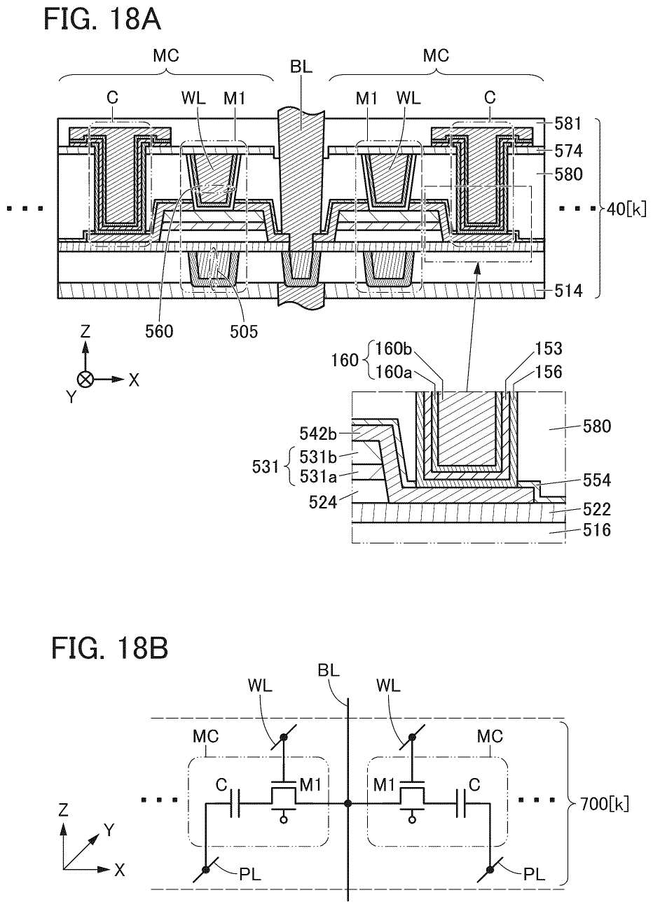

FIG. 18A illustrates a cross-sectional structure example of the element layer 40[k] applicable to the element layer 30 and the element layer 40[1] to the element layer 40[3] illustrated in FIG. 16. FIG. 18B is an equivalent circuit diagram of FIG. 18A. FIG. 18A illustrates an example where two memory cells MC are electrically connected to one wiring BL.

Note that the transistor MI is a variation example of the transistor 500. Specifically, the transistor M1 is different from the transistor 500 in that the conductor 542a and the conductor 542b extend beyond an end portion of a metal oxide 531 (a metal oxide 531a and a metal oxide 531b).

The memory cell MC illustrated in FIG. 18A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. The conductor 160 is electrically connected to the wiring PL (not illustrated in FIG. 18A).

The capacitor C is formed in an opening portion that is provided by removal of part of the insulator 574, part of the insulator 580, and part of an insulator 554. The conductor 156, the insulator 580, and the insulator 554 are formed along the side surface of the opening portion, and thus are preferably deposited by an ALD method, a CVD method, or the like.

A conductor that can be used for a conductor 505 or the conductor 560 is used for each of the conductor 156 and the conductor 160. For example, titanium nitride formed by an ALD method is used for the conductor 156. Furthermore, titanium nitride formed by an ALD method is used for the conductor 160a, and tungsten formed by a CVD method is used for the conductor 160b. Note that in the case where the adhesion of tungsten to the insulator 153 is sufficiently high, a single-layer film of tungsten formed by a CVD method may be used for the conductor 160.

As the insulator 153, an insulator of a high permittivity (high-k) material (material with a high relative permittivity) is preferably used. As the insulator of a high permittivity material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, or nitride may contain silicon. Insulating layers each formed of any of the above-described materials can be stacked to be used. The insulator 153 can employ, for example, a three-layer stacked structure of zirconium oxide, aluminum oxide, and zirconium oxide. Note that the three-layer stacked structure may be referred to as ZrOₓₐ\AlO_{xb}\ZrO_{xc} (ZAZ). Note that xa, xb, and xc described above each have an arbitrary unit.

As the insulator of a high permittivity material, it is possible to use, for example, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, or an oxynitride containing hafnium and zirconium. Using such a high permittivity material allows the insulator 153 to be thick enough to inhibit an off-state current and a sufficiently high capacitance of the capacitor C to be ensured.

It is preferable to use stacked insulating layers each formed of any of the above-described materials. A stacked-layer structure using a high permittivity material and a material having higher dielectric strength than the high permittivity material is preferably used. For example, as the insulator 153, an insulating film in which zirconium oxide, aluminum oxide, and zirconium oxide are stacked in this order can be used. As another example, an insulating film in which zirconium oxide, aluminum oxide, zirconium oxide, and aluminum oxide are stacked in this order can be used. As another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor C.

Alternatively, a material that can have ferroelectricity may be used for the insulator 153. Examples of the material that can have ferroelectricity include metal oxides such as hafnium oxide, zirconium oxide, and HfZrO_{X} (X is a real number greater than 0). Other examples of the material that can have ferroelectricity include a material in which an element J1 (the element J1 here is one or more selected from zirconium, silicon, aluminum, gadolinium, yttrium, lanthanum, strontium, and the like) is added to hafnium oxide. Here, the atomic ratio of hafnium atom to the element J1 can be set as appropriate; the atomic ratio of hafnium atom to the element J1 is, for example, 1:1 or in the neighborhood thereof. Other examples of the material that can have ferroelectricity include a material in which an element J2 (the element J2 here is one or more selected from hafnium, silicon, aluminum, gadolinium, yttrium, lanthanum, strontium, and the like) is added to zirconium oxide. The atomic ratio of zirconium atom to the element J2 can be set as appropriate; the atomic ratio of zirconium atom to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used. Alternatively, the material that can have ferroelectricity can employ a structure in which a Group 3 element (also referred to as a Group IIIa element) in the periodic table is added to a metal oxide such as hafnium oxide, zirconium oxide, or HfZrO_{X} (X is a real number greater than 0). The Group 3 element in the periodic table is further preferably one or more selected from scandium, lanthanum, and yttrium and is still further preferably one or both of lanthanum and yttrium. Note that in this specification and the like, a Group 3 element in the periodic table is simply referred to as a Group 3 element in some cases.

### NOSRAM Structure Example

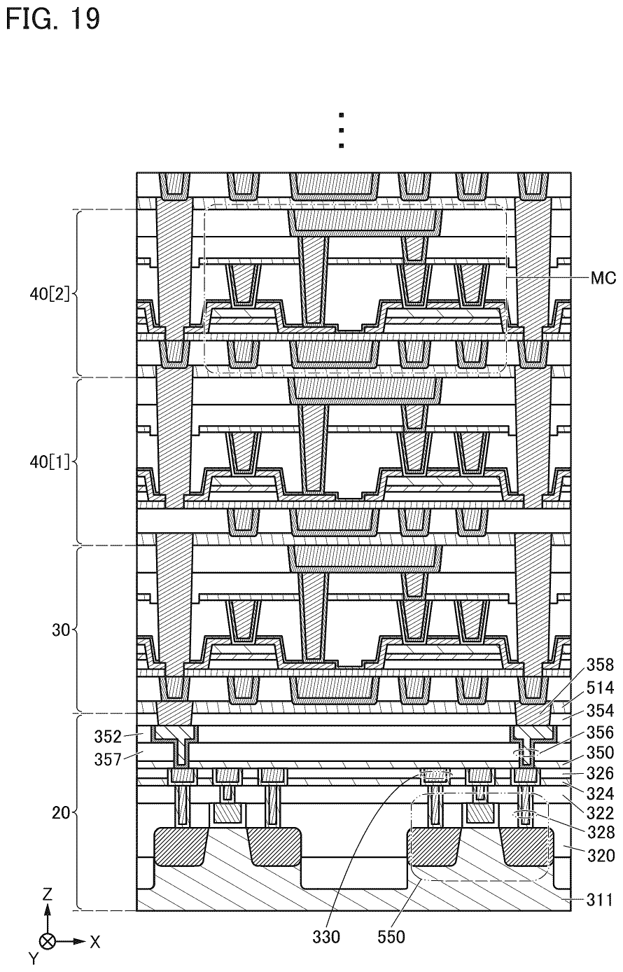

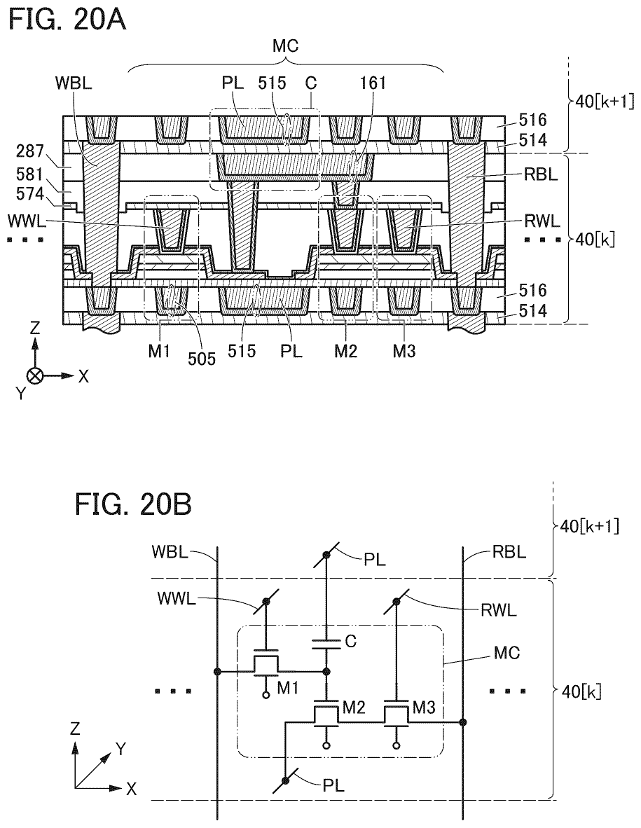

FIG. 19 illustrates a cross-sectional structure example of the case of using a NOSRAM memory cell circuit structure. Note that FIG. 19 is also a variation example of FIG. 16. FIG. 20A illustrates a cross-sectional structure example of the element layer 40[k]. FIG. 20B is an equivalent circuit diagram of FIG. 20A.

The memory cell MC illustrated in FIG. 19 and FIG. 20A includes the transistor M1, a transistor M2, and a transistor M3 over the insulator 514. A conductor 515 is provided over the insulator 514. The conductor 515 and the conductor 505 can be concurrently formed using the same material in the same step.

The transistor M2 and the transistor M3 illustrated in FIG. 19 and FIG. 20A share one island-shaped metal oxide 531. In other words, a part of the one island-shaped metal oxide 531 functions as a channel formation region of the transistor M2, and another part thereof functions as a channel formation region of the transistor M3. Furthermore, a source of the transistor M2 serves also as a drain of the transistor M3, or a drain of the transistor M2 serves also as a source of the transistor M3. Thus, the area occupied by the transistor M2 and the transistor M3 is smaller than that of the case where the transistor M2 and the transistor M3 are independently provided.

In the memory cell MC illustrated in FIG. 19 and FIG. 20A, an insulator 287 is provided over the insulator 581, and a conductor 161 is embedded in the insulator 287. The insulator 514 of the element layer 40[k+1] is provided over the insulator 287 and the conductor 161.

In FIG. 19 and FIG. 20A, the conductor 515 of the element layer 40[k+1] functions as one terminal of the capacitor C, the insulator 514 of the element layer 40[k+1] functions as a dielectric of the capacitor C, and the conductor 161 functions as the other terminal of the capacitor C. The other of a source and a drain of the transistor M1 is electrically connected to the conductor 161 through a contact plug, and a gate of the transistor M2 is electrically connected to the conductor 161 through another contact plug.

### DOSRAM Structure Example 2

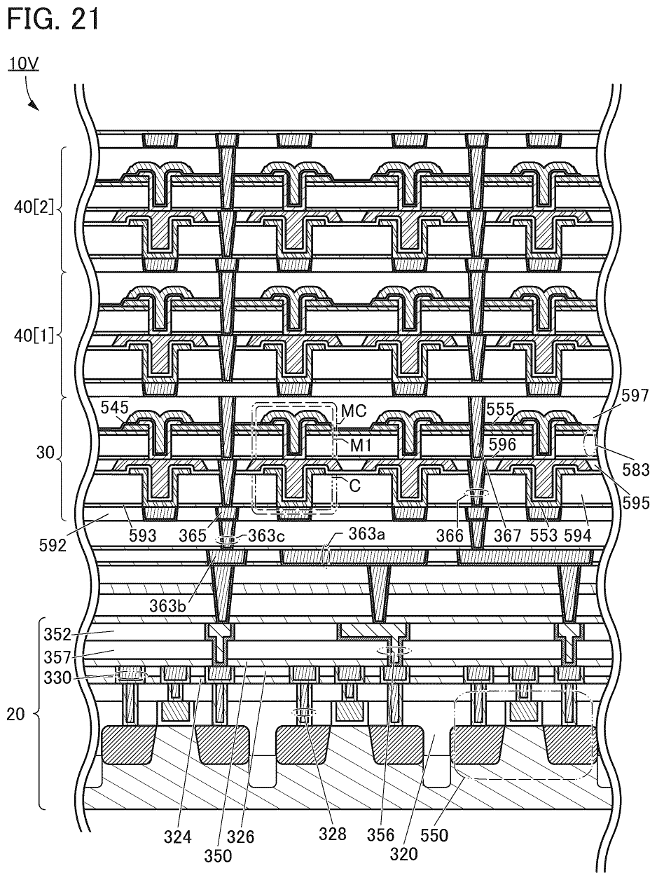

FIG. 21 illustrates a cross-sectional structure example of stacked element layers including OS transistors, which can be used for the semiconductor device of one embodiment of the present invention or the like and is different from those in FIG. 16 to FIG. 20A and FIG. 20B. In a semiconductor device 10V illustrated in FIG. 21, the capacitor C is provided below the transistor M1 in the memory cell MC provided in each of the element layer 30 and the element layer 40[1] to the element layer 40[2] illustrated in FIG. 21.

In FIG. 21, the element layer 30 and the plurality of element layers 40 each include a plurality of the memory cells MC. In the memory cell MC illustrated in FIG. 21, the transistor MI and the capacitor C are illustrated.

A conductor 363a, a conductor 363b, and a conductor 363c are embedded in an interlayer film between the element layer 20 and the element layer 30. In each of the element layer 30 and the plurality of element layers 40, a conductor 365 is embedded in an insulator 592 described later. In each of the element layer 30 and the plurality of element layers 40, a conductor 366 is embedded in an insulator 593, an insulator 594, an insulator 553, and an insulator 595 that are described later. In each of the element layer 30 and the plurality of element layers 40, a conductor 367 is embedded in an insulator 596, an insulator 583, the conductor 542b, the insulator 555, and an insulator 597 that are described later. The conductor 363a, the conductor 363b, the conductor 363c, the conductor 365, the conductor 366, and the conductor 367 each function as a via hole, a contact plug, or a wiring.

Next, a structure example of the memory cell MC included in each of the element layer 30 and the plurality of element layers 40 of the semiconductor device 10V in FIG. 21 is described.

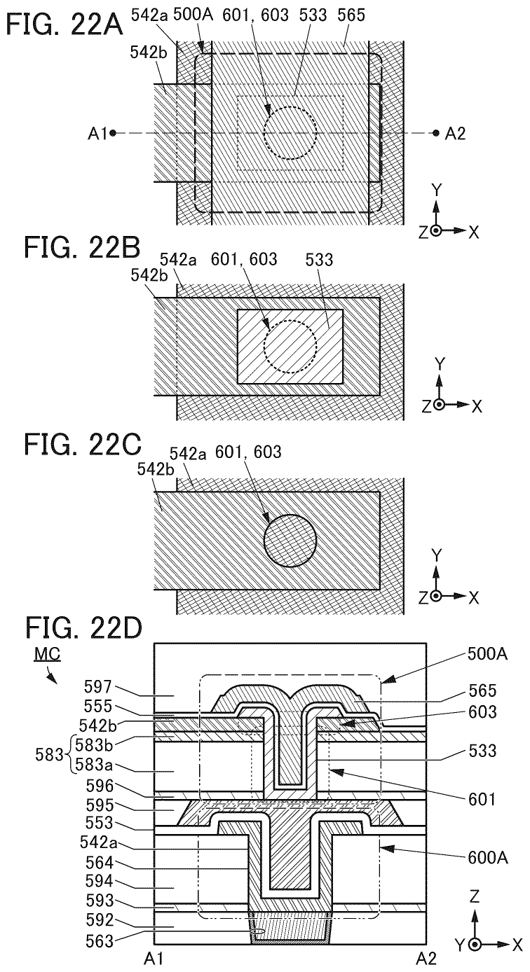

FIG. 22A is a plan view illustrating a structure example of the memory cell MC included in each of the element layer 30 and the plurality of element layers 40 of the above semiconductor device 10V and the periphery of the memory cell MC. Note that in FIG. 22A to FIG. 22D, a transistor 500A corresponds to the transistor M1 in FIG. 21, and a capacitor 600A corresponds to the capacitor C in FIG. 21. FIG. 22D is a cross-sectional view along the dashed-dotted line A1-A2 in FIG. 22A. Note that in FIG. 22A, some components of the transistor M1, such as an insulator, are not illustrated. Also in the following plan views of the transistor, some components such as an insulator are not illustrated.

The capacitor 600A includes the insulator 593, the insulator 594, the insulator 553, the insulator 595, a conductor 563, a conductor 564, and the conductor 542a, for example.

The conductor 563 is embedded in the conductor 563. The conductor 563 can be, for example, the wiring PL extending in the Y direction.

The insulator 593 and the insulator 594 are formed in this order over the insulator 592 and the conductor 563, for example. In the insulator 593 and the insulator 594, an opening is provided in a region overlapping the conductor 563. The conductor 564 is formed on the bottom surface (over the conductor 563) and the side surface of the opening. Note that in FIG. 22D, the conductor 564 is formed also on the top surface of the insulator 594. The insulator 553 is formed over the insulator 594 and the conductor 564. The conductor 542a is formed to cover a region of the insulator 553 that overlaps the conductor 564. The insulator 595 is formed over the conductor 542a and the insulator 553. Note that the top surface of the insulator 595 and the top surface of the conductor 542a are preferably substantially level with each other. Thus, the insulator 595 and the conductor 542a are preferably planarized by planarization treatment using a chemical mechanical polishing (CMP) method or the like, for example.

The conductor 564 corresponds to one of a pair of terminals of the capacitor 600A, for example. The conductor 542a corresponds to the other of the pair of terminals of the capacitor 600A, for example.

The insulator 553 functions as a dielectric sandwiched between the pair of terminals of the capacitor 600A, for example.

The transistor 500A is provided above the conductor 542a and the insulator 595 of the capacitor 600A.

In the transistor 500A, the channel length direction is not substantially parallel to the substrate 311 but along the side surface of a later-described opening provided in the insulator 583.

The transistor 500A includes the conductor 542a functioning as one of the source electrode and the drain electrode, the conductor 542b functioning as the other of the source electrode and the drain electrode, a metal oxide 533, the insulator 555, and a conductor 565 functioning as a gate electrode, for example. FIG. 22A illustrates an example in which the conductor 542b extends in the direction perpendicular to the conductor 542a and the conductor 565. Note that as described above, the conductor 542a functions also as the other of the pair of electrodes of the capacitor 600A.

For the metal oxide 533, the material that can be used for the oxide 530 included in the above-described transistor 500 can be used, for example.

In FIG. 22A and FIG. 22D of this embodiment, the direction in which the conductor 542b extends is referred to as the X direction. The direction perpendicular to the X direction and parallel to the top surface of the conductor 563, for example, is referred to as the Y direction, and the direction perpendicular to the top surface of the conductor 563 is referred to as the Z direction. The definition of the X direction, the Y direction, and the Z direction applies to the following drawings in some cases. The X direction, the Y direction, and the Z direction can be perpendicular to each other. In the description of a plan view in this specification and the like, the X direction may be referred to as the right side or the left side and the Y direction may be referred to as the upper side or the lower side. In some cases, the right side, the left side, the upper side, and the lower side can be respectively referred to as the X direction, the-X direction, the Y direction, and the-Y direction.

The conductor 542a functions as one of the source electrode and the drain electrode of the transistor 500A. The conductor 542b functions as the other of the source electrode and the drain electrode of the transistor 500A. The insulator 555 functions as a gate insulating layer of the transistor 500A. The conductor 565 functions as the gate electrode of the transistor 500A.

In the metal oxide 533 between the source electrode and the drain electrode, the whole of the region overlapped by the gate electrode with the gate insulating layer therebetween functions as the channel formation region. The metal oxide 533 including a region functioning as the channel formation region is referred to as a semiconductor layer in some cases. In the metal oxide 533, a region in contact with the source electrode functions as a source region, and a region in contact with the drain electrode functions as a drain region.

The insulator 596 is provided over the insulator 595 and the conductor 542a. The insulator 596 can have a function of an interlayer insulating layer. The interlayer insulating layer here can be a barrier insulating film that inhibits diffusion of impurities such as water and hydrogen (e.g., one or both of a hydrogen atom and a hydrogen molecule).

The insulator 583 (an insulator 583a and an insulator 583b) is provided over the insulator 596, and the conductor 542b is provided over the insulator 583. The insulator 583 can have a function of an interlayer insulating layer. The interlayer insulating layer here can be an interlayer film for separation of the source electrode and the gate electrode in 500A.

For the insulator 583a, an oxide or an oxynitride is preferably used, for example. For the insulator 583a, a film from which oxygen is released by heating is preferably used. For the insulator 583a, silicon oxide or silicon oxynitride can be suitably used, for example. Oxygen release from the insulator 583a enables oxygen supply from the insulator 583a to the metal oxide 533. When oxygen is supplied from the insulator 583a to the metal oxide 533, in particular, the channel formation region of the metal oxide 533, oxygen vacancies in the metal oxide 533 and hydrogen that enters the oxygen vacancies can be reduced. Consequently, the transistor 500A can have favorable electrical characteristics and high reliability.

The insulator 583b preferably includes a region having a higher nitrogen content than the insulator 583a, for example. For example, silicon nitride or silicon nitride oxide can be suitably used for the insulator 583b. When silicon nitride or silicon nitride oxide is used for the insulator 583b, the insulator 583b can serve as a blocking layer that inhibits release of oxygen from the insulator 583a. Although the insulator 583 has a three-layer stacked structure in this embodiment, the present invention is not limited thereto. For example, the insulator 583 may be a single layer. In this case, a barrier insulating film that inhibits diffusion of impurities such as water and hydrogen (e.g., one or both of a hydrogen atom and a hydrogen molecule), typically silicon nitride, is used for the insulator 583.

The insulator 596 and the insulator 583 each include an opening 601 reaching the conductor 542a. The conductor 542b includes an opening 603 reaching the opening 601. That is, the opening 603 includes a region overlapping the opening 601.

FIG. 22A illustrates, as the components of the transistor 500A, the conductor 542a, the conductor 542b, the metal oxide 533, the conductor 565, the opening 601, and the opening 603. FIG. 22B illustrates a structure example in which the conductor 565 is omitted from the components illustrated in FIG. 22A. In other words, FIG. 22B illustrates the conductor 542a, the conductor 542b, the metal oxide 533, the opening 601, and the opening 603. FIG. 22C illustrates a structure example in which the metal oxide 533 is further omitted from the components illustrated in FIG. 22B. In other words, FIG. 22C illustrates the conductor 542a, the conductor 542b, the opening 601, and the opening 603.

As illustrated in FIG. 22C and FIG. 22D, the conductor 542b includes the opening 603 in a region overlapping the conductor 542a. As illustrated in FIG. 22C, the conductor 542b can be formed to entirely surround the periphery of the opening 601 in a plan view. It is preferable that the conductor 542b not be provided in the opening 601. In other words, it is preferable that the conductor 542b be not in contact with the side surface of the insulator 583 on the opening 601 side.

FIG. 22A to FIG. 22C illustrate an example in which the opening 601 and the opening 603 are circular in a plan view. In the case where the planar shapes of the opening 601 and the opening 603 are circular, the processing accuracy of forming the opening 601 and the opening 603 can be increased, and the opening 601 and the opening 603 having minute sizes can be formed. Note that in this specification and the like, a circular shape is not necessarily a perfect circle. For example, the planar shapes of the opening 601 and the opening 603 may be elliptical or a shape including a curve. Alternatively, a polygonal shape may be employed.

FIG. 22D illustrates an example in which the end portion of the conductor 542b on the opening 603 side is aligned with or substantially aligned with the end portion of the insulator 583 on the opening 601 side. In other words, the planar shape of the opening 603 is the same or substantially the same as the planar shape of the opening 601. Note that in this specification and the like, the end portion of the conductor 542b on the opening 603 side refers to the end portion of the bottom surface of the conductor 542b on the opening 603 side. The bottom surface of the conductor 542b refers to the surface on the insulator 583 side. The end portion of the insulator 583 on the opening 601 side refers to the end portion of the top surface of the insulator 583 on the opening 601 side. The top surface of the insulator 583 refers to the surface on the conductor 542b side. The planar shape of the opening 603 refers to the planar shape of the end portion of the bottom surface of the conductor 542b on the opening 603 side. The planar shape of the opening 601 refers to the planar shape of the end portion of the top surface of the insulator 583 on the opening 601 side.

In the case where end portions are aligned or substantially aligned with each other, the end portions can also be said to match or substantially match. In the case where end portions are aligned or substantially aligned with each other and the case where planar shapes are the same or substantially the same, it can be said that outlines of at least partly overlap each other in a plan view. For example, the case of processing the upper layer and the lower layer with the use of the same mask pattern or mask patterns that are partly the same is included. Note that, in some cases, the outlines do not completely overlap each other and the upper layer is positioned inside the lower layer or the upper layer is positioned outside the lower layer; such cases are also represented by the expression “end portions substantially match” or the expression “planar shapes are substantially the same”.

The opening 601 can be formed using a resist mask used for the formation of the opening 603, for example. Specifically, first, the insulator 596 over the conductor 542a and the insulator 595, the insulator 583 over the insulator 596, a conductive film to be the conductor 542b over the insulator 583, and a resist mask over the conductive film are formed. Then, the opening 603 is formed in the conductive film by using the resist mask and then the opening 601 is formed in the insulator 596 and the insulator 583 by using the resist mask, whereby the end portion of the opening 601 and the end portion of the opening 603 can be aligned or substantially aligned with each other. With such a structure, the process can be simplified.

The metal oxide 533 is provided to include a region positioned in the opening 601 and the opening 603 to cover the opening 601 and the opening 603. The metal oxide 533 has a shape along the top surface and the side surface of the conductor 542b, the side surface of the insulator 583, the side surface of the insulator 596, and the top surface of the conductor 542a. The metal oxide 533 includes, for example, a region in contact with the top surface and the side surface of the conductor 542b, the side surface of the insulator 583, and the top surface of the conductor 542a.

The metal oxide 533 preferably covers the end portion of the conductor 542b on the opening 603 side. For example, FIG. 22D illustrates a structure in which the end portion of the metal oxide 533 is positioned over the conductor 542b. In other words, the end portion of the metal oxide 533 is in contact with the top surface of the conductor 542b.

Although the metal oxide 533 has a single-layer structure in FIG. 22D as an example, one embodiment of the present invention is not limited thereto. The metal oxide 533 may have a stacked-layer structure of two or more layers.

The insulator 555 functioning as the gate insulating layer of the transistor 500A is provided to include a region positioned in the opening 601 and the opening 603 to cover the opening 601 and the opening 603. The insulator 555 is provided over the metal oxide 533, the conductor 542b, and the insulator 583. The insulator 555 can include a region in contact with the top surface and the side surface of the metal oxide 533, the top surface and the side surface of the conductor 542b, the top surface of the insulator 583, and the top surface of the insulator 596. The insulator 555 has a shape along the top surface of the insulator 596, the top surface of the insulator 583, the top surface and the side surface of the conductor 542b, and the top surface and the side surface of the metal oxide 533.

The conductor 565 functioning as the gate electrode of the transistor 500A is provided over the insulator 555 and can include a region in contact with the top surface of the insulator 555. The conductor 565 includes a region overlapping the metal oxide 533 with the insulator 555 therebetween. The conductor 565 has a shape along the shape of the top surface of the insulator 555.

For example, as illustrated in FIG. 22D, the conductor 565 includes a region overlapping the metal oxide 533 with the insulator 555 therebetween in the opening 601 and the opening 603. In the example illustrated in FIG. 22D, the conductor 565 includes a region overlapping the conductor 542a and the conductor 542b with the insulator 555 and the metal oxide 533 therebetween. The conductor 565 covers the entire metal oxide 533. Such a structure enables a gate electric field to be applied to the entire metal oxide 533; thus, the transistor 500A can have better electrical characteristics, for example, a higher on-state current.

The transistor 500A is what is called a top-gate transistor including a gate electrode above the metal oxide 533. Furthermore, since the bottom surface of the metal oxide 533 includes a region in contact with the source electrode and the drain electrode, the transistor 500A can be referred to as a TGBC (Top Gate Bottom Contact) transistor.

The transistor 500A is a transistor in which at least part of a semiconductor layer including a channel formation region is provided along the side surface of an insulating layer in an opening formed in the insulating layer. In this specification and the like, such a transistor is referred to as a vertical transistor in some cases.

Note that in a vertical transistor, a source electrode and a drain electrode are positioned at different heights, which causes current flow in the height direction (vertical direction) in a channel formation region of a semiconductor layer. In other words, the channel length direction can be regarded as having a component of the height direction (vertical direction). Thus, the above-described vertical transistor can also be referred to as a VFET (Vertical Field Effect Transistor), a vertical-channel transistor, a vertical-channel-type transistor, or the like.

In a vertical transistor, a source region, a channel formation region, and a drain region can at least partly overlap in a top view, enabling a smaller occupied area (footprint). Such a transistor enables reduced channel length and increased channel width, reducing on-state resistance (increasing on-state current).

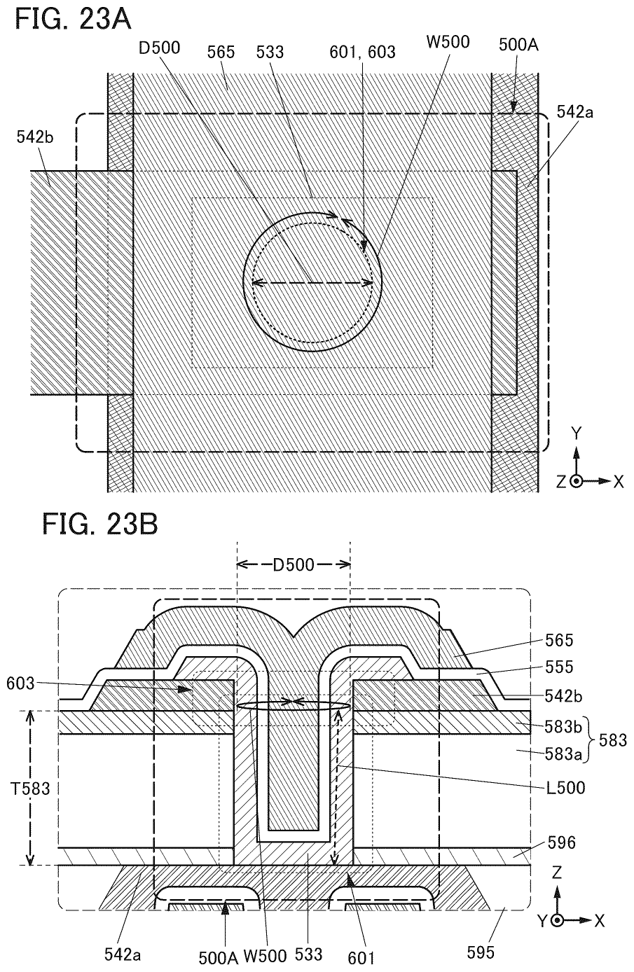

Here, the channel length and channel width of the transistor 500A are described with reference to FIG. 23A and FIG. 23B. FIG. 23A is an enlarged view of the plan view of FIG. 22A illustrating the structure example of the transistor 500A and the vicinity thereof. FIG. 23B is an enlarged view of the cross-sectional view of FIG. 22D illustrating the structure example of the transistor 500A and the vicinity thereof.

In the metal oxide 533, a region in contact with the conductor 542a functions as one of the source region and the drain region, a region in contact with the conductor 542b functions as the other of the source region and the drain region, and a region between the source region and the drain region functions as the channel formation region.

The channel length of the transistor 500A is a distance between the source region and the drain region. In FIG. 23B, a channel length L500 of the transistor 500A is indicated by a dashed double-headed arrow. In the cross-sectional view, the channel length L500 is a distance between the end portion of the region where the metal oxide 533 is in contact with the conductor 542a and the end portion of the region where the metal oxide 533 is in contact with the conductor 542b.

Here, the channel length L500 of the transistor 500A corresponds to the length of the side surface of the insulator 583 on the opening 601 side when seen from the XZ plane. That is, the channel length L500 is determined by a thickness T583 of the insulator 583 and is not affected by the performance of a light-exposure apparatus used for manufacturing the transistor. Thus, the channel length L500 can be a value smaller than that of the resolution limit of the light-exposure apparatus, which enables the transistor to have a minute size. For example, the channel length L500 is preferably greater than or equal to 0.0010 μm, i.e., greater than or equal to 1 nm and is preferably greater than or equal to 0.010 μm and less than 3.0 um, further preferably greater than or equal to 0.050 μm and less than 3.0 μm, still further preferably greater than or equal to 0.10 μm and less than 3.0 82 m, yet further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. In FIG. 23B, the thickness T583 of the insulator 583 is indicated by a dashed-dotted double-headed arrow.

When the transistor 500A is used as a transistor included in the memory cell MC, the memory cell MC can be miniaturized. This can increase the storage density, so that the semiconductor device can have a large storage capacity. Furthermore, when the channel length L500 is reduced, the on-state current of the transistor 500A can be increased, so that the memory cell MC can be driven at high speed.

The channel length L500 can be controlled by adjustment of the thickness T583 of the insulator 596 and the insulator 583.

The thickness T583 of the insulator 596 and the insulator 583 is preferably greater than or equal to 0.0010 μm, i.e., greater than or equal to 1 nm and is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 um.

Although FIG. 23B, for example, illustrates the structure in which the side surfaces of the insulator 596 and the insulator 583 on the opening 601 side are linear in the cross-sectional view, one embodiment of the present invention is not limited thereto. In the cross-sectional view, the side surfaces of the insulator 596 and the insulator 583 on the opening 601 side may be curved, or the side surfaces may include both a linear region and a curved region.

The channel width of the transistor 500A is the width of the source region or the width of the drain region in the direction orthogonal to the channel length direction. In other words, the channel width is the width of the region where the metal oxide 533 is in contact with the conductor 542a or the width of the region where the metal oxide 533 is in contact with the conductor 542b in the direction orthogonal to the channel length direction. Here, the channel width of the transistor 500A is described as the width of the region where the metal oxide 533 is in contact with the conductor 542b in the direction orthogonal to the channel length direction. In FIG. 23A and FIG. 23B, a channel width W500 of the transistor 500A is indicated by a solid double-headed arrow. In the plan view, the channel width W500 is the length of the end portion of the bottom surface of the conductor 542b on the opening 603 side.

The channel width W500 is determined by the planar shape of the opening 603. In FIG. 23A and FIG. 23B, a width D500 of the opening 603 is indicated by a dashed-two dotted double-headed arrow. In the plan view, the width D500 corresponds to the short side of the smallest rectangle that is circumscribed around the opening 603. In the case where the opening 603 is formed by a photolithography method, the width D500 of the opening 603 is larger than or equal to the resolution limit of a light-exposure apparatus. For example, the width D500 is preferably greater than or equal to 0.20 μm and less than 5.0 μm, further preferably greater than or equal to 0.20 μm and less than 4.5 μm, still further preferably greater than or equal to 0.20 μm and less than 4.0 μm, yet further preferably greater than or equal to 0.20 μm and less than 3.5 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. Note that when the planar shape of the opening 603 is circular, the width D500 corresponds to the diameter of the opening 603, and the channel width W500 can be equal to the length of the perimeter of the opening 603 in a plan view and calculated to be “D500×π”.

Since the size of the transistor 500A is small, the use of the transistor 500A in the element layer 30 and the plurality of element layers 40 can increase the storage density and thus provide a semiconductor device including a storage portion with a large storage capacity. Since the operating speed of the transistor 500A is high, the use of the transistor 500A in a semiconductor device can achieve a semiconductor device with high driving speed. Since the electrical characteristics of the transistor 500A are stable, the use of the transistor 500A for a semiconductor device can achieve a semiconductor device with high reliability. Since the amount of off-state current of the transistor 500A is small, the use of the transistor 500A for a semiconductor device can achieve a semiconductor device with low power consumption.

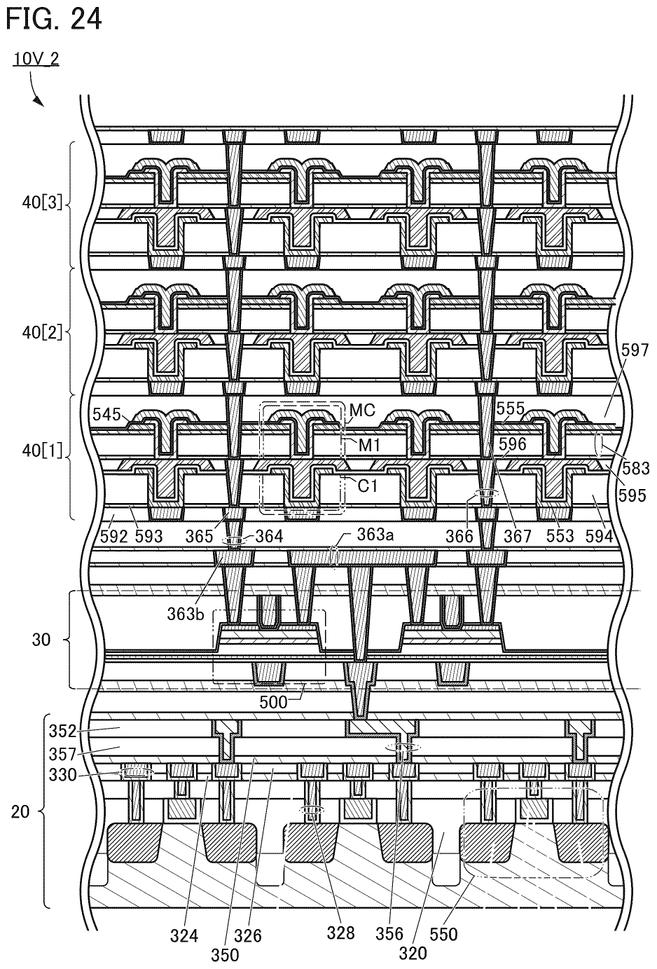

Note that the transistor 500A can also be used as a transistor included in a circuit different from the memory cell MC, for example. Moreover, the transistor 500A can be used in combination with another transistor structure, for example, in combination with the element layer 30 including the transistor 500, which is described with reference to FIG. 17, as in a semiconductor device 10V_2 illustrated in FIG. 24. Such a structure allows transistors having different transistor characteristics to be stacked, enabling circuit arrangement based on the switching characteristics.

This embodiment can be implemented in combination with the other embodiments described in this specification as appropriate.

### Embodiment 4

This embodiment will describe an electronic component, an electronic device, a large computer, space equipment, and a data center (also referred to as a DC) in which the semiconductor device described in the above embodiment can be used. An electronic component, an electronic device, a large computer, space equipment, and a data center in which the semiconductor device of one embodiment of the present invention is used are effective in improving performance, e.g., reducing power consumption.

### Electronic Component

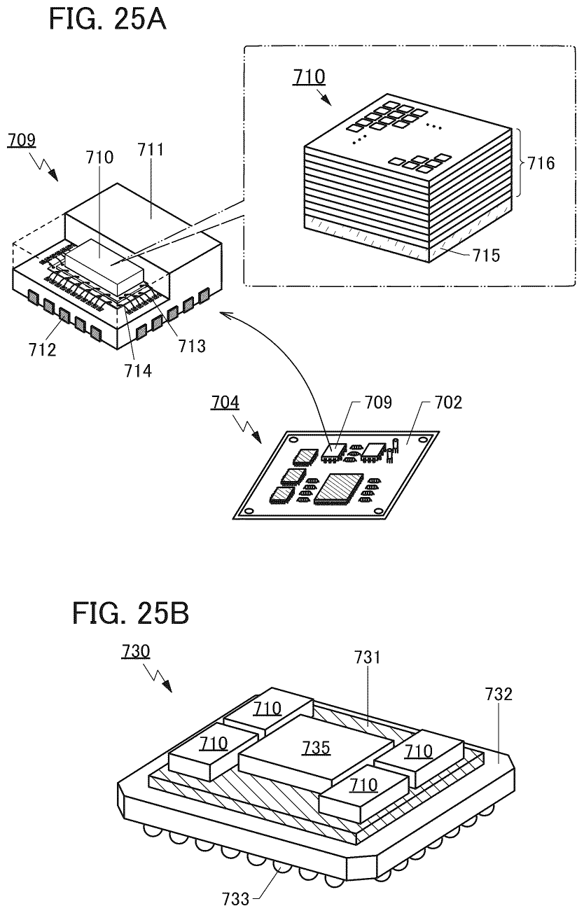

FIG. 25A illustrates a perspective view of a substrate (a circuit board 704) on which an electronic component 709 is mounted. The electronic component 709 illustrated in FIG. 25A includes a semiconductor device 710 in a mold 711. FIG. 25A omits illustrations of some parts to show the inside of the electronic component 709. The electronic component 709 includes a land 712 outside the mold 711. The land 712 is electrically connected to an electrode pad 713, and the electrode pad 713 is electrically connected to the semiconductor device 710 through a wire 714. The electronic component 709 is mounted on a printed circuit board 702, for example. A plurality of such electronic components are combined and electrically connected to each other on the printed circuit board 702, which forms the circuit board 704.

The semiconductor device 710 includes a driver circuit layer 715 and a storage layer 716. The storage layer 716 has a structure in which a plurality of memory cell arrays are stacked. A stacked-layer structure of the driver circuit layer 715 and the storage layer 716 can be a monolithic stacked-layer structure. In the monolithic stacked-layer structure, layers can be connected to each other without using a through electrode technique such as a TSV (Through Silicon Via) and a bonding technique such as Cu-to-Cu direct bonding. The monolithic stacked-layer structure of the driver circuit layer 715 and the storage layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed; thus, the number of connection pins can be increased. An increase in the number of connection pins enables parallel operations, which can increase the bandwidth of the memory (also referred to as memory bandwidth).

It is preferable that the plurality of memory cell arrays included in the storage layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the storage layer 716 is formed using Si transistors, it is difficult to obtain the monolithic stacked-layer structure as compared with the case where the storage layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 25B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of the semiconductor devices 710 are provided on the interposer 731.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in an expansion coefficient between an integrated circuit and the interposer does not easily occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 25B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### Electronic Device

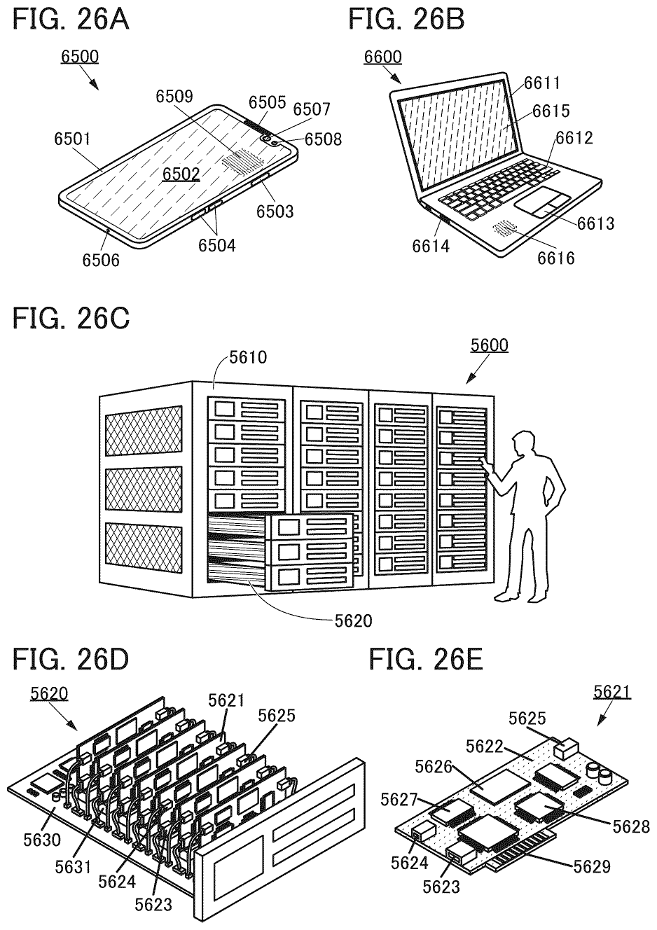

FIG. 26A is a perspective view of an electronic device 6500. The electronic device 6500 illustrated in FIG. 26A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a semiconductor device, for example. The semiconductor device of one embodiment of the present invention can be used for the display portion 6502, the control device 6509, and the like.

An electronic device 6600 illustrated in FIG. 26B is an information terminal that can be used as a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a semiconductor device, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### Large Computer

FIG. 26C is a perspective view of a large computer 5600. In the large computer 5600 illustrated in FIG. 26C, a plurality of rack mount computers 5620 are stored in a rack 5610. Note that the large computer 5600 may be referred to as a supercomputer.

The computer 5620 can have a structure in a perspective view of FIG. 26D, for example. In FIG. 26D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26E is an example of a processing board provided with a CPU, a GPU, a semiconductor device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 26E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a semiconductor device. As the semiconductor device 5628, the electronic component 709 can be used, for example. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### Space Equipment

The semiconductor device of one embodiment of the present invention can be suitably used for space equipment, such as equipment that processes and stores information.

The semiconductor device of one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in outer space.

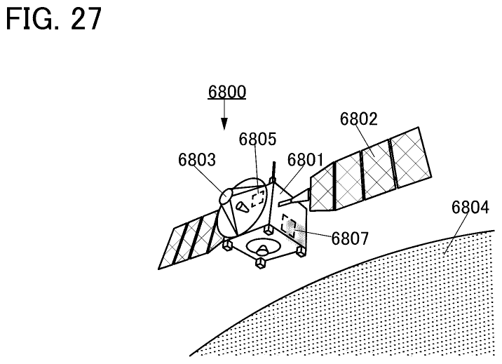

FIG. 27 illustrates an artificial satellite 6800 as an example of space equipment. The artificial satellite 6800 includes a body 6801, a solar panel 6802, an antenna 6803, a secondary battery 6805, and a control device 6807. In FIG. 27, a planet 6804 in outer space is illustrated as an example. Note that outer space refers to, for example, space at an altitude greater than or equal to 100 km, and outer space described in this specification may include the thermosphere, mesosphere, and stratosphere.

Although not illustrated in FIG. 27, the secondary battery 6805 may be provided with a battery management system (also referred to as BMS) or a battery control circuit. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, power required for the operation of the artificial satellite 6800 is generated. However, for example, in the situation where the solar panel is not irradiated with sunlight or in the situation where the amount of sunlight with which the solar panel is irradiated is small, the amount of generated power is small. Accordingly, power required for the operation of the artificial satellite 6800 might not be generated. In order to operate the artificial satellite 6800 even with a small amount of generated power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a semiconductor device, for example. Note that the semiconductor device of one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, and a space probe, for example.

As described above, an OS transistor has excellent effects of achieving a wide memory bandwidth and being highly resistant to radiation as compared with a Si transistor.

### Data Center

The semiconductor device of one embodiment of the present invention can be suitably used for, for example, a storage system employed in a data center or the like. Long-term data management, such as a guarantee for data immutability, is required for the data center. The long-term management of data needs an increase in building size for, for example, setting a storage and a server for storing an enormous amount of data, ensuring stable power supply for data retention, and ensuring cooling equipment for data retention.

With the use of the semiconductor device of one embodiment of the present invention for the storage system used in the data center, electric power required for data retention can be reduced and a semiconductor device retaining data can be downsized. Thus, downsizing of the storage system, downsizing of the power supply for data retention, downscaling of the cooling equipment, and the like can be achieved, for example. This can reduce the space of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

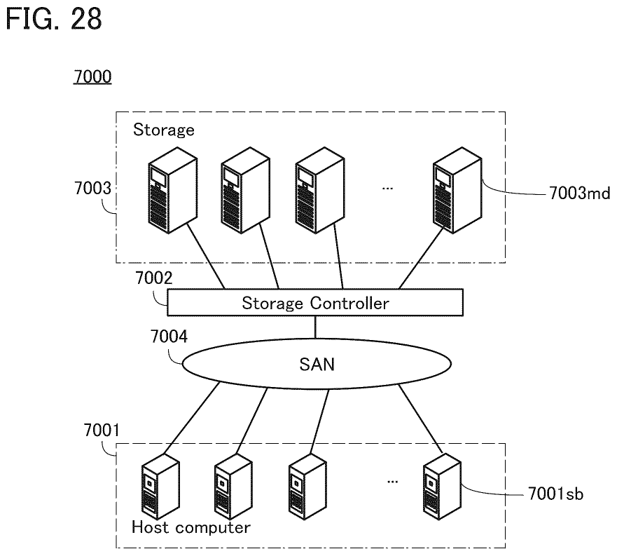

FIG. 28 illustrates a storage system that can be used in a data center. A storage system 7000 illustrated in FIG. 28 includes a plurality of servers 7001sb as a host 7001 (indicated as “Host Computer” in the diagram). The storage system 7000 also includes a plurality of semiconductor devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

The configurations, structures, methods, and the like described in this embodiment can be used in an appropriate combination with any of the configurations, structures, methods, and the like described in the other embodiments and the like.

### EXAMPLE 1

In this example, a transistor and a memory device of embodiments of the present invention were fabricated.

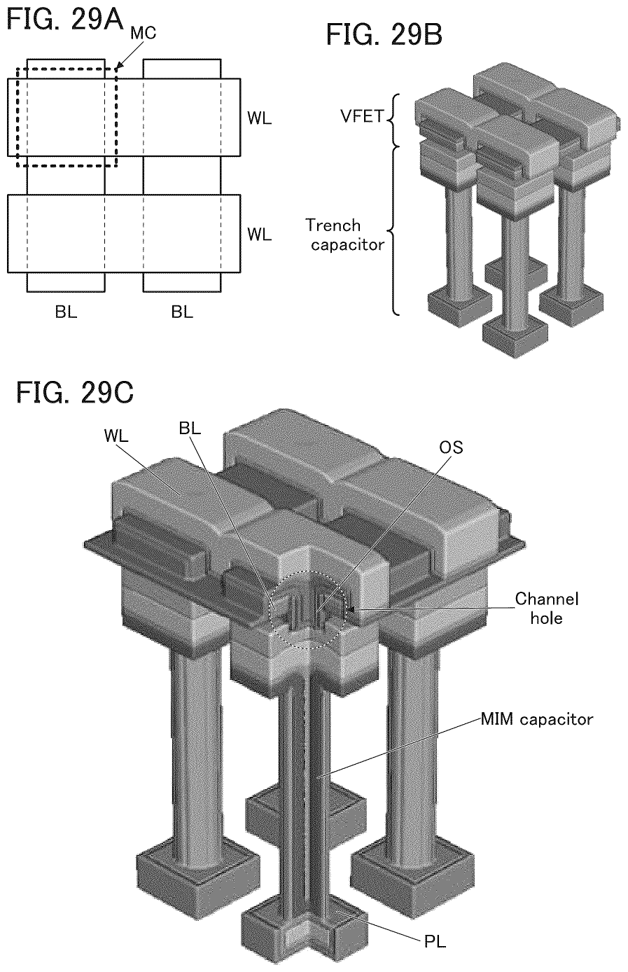

First, the structure of the fabricated memory device is described. FIG. 29A is a schematic top view of the memory device, and FIG. 29B is a schematic perspective view thereof.

The memory device includes a plurality of wirings WL and a plurality of wirings BL. One memory cell MC is placed in a portion where the wiring WL and the wiring BL intersect with each other. In the memory cell MC, a vertical transistor (VFET) and a trench capacitor thereunder are stacked. For example, when the arrangement interval between the memory cells MC is 120 nm in both the vertical and horizontal directions, the area of the memory cell MC is 0.0144 μm². In this example, a memory device in which the arrangement interval between the memory cells MC was 260 nm in both the vertical and horizontal directions was fabricated.

FIG. 29C is a perspective view in which part of FIG. 29B is cut away. The vertical transistor includes an oxide semiconductor film (OS) in an opening portion (Channel hole) provided in an interlayer insulating film. As the trench capacitor, a MIM (Metal Insulator Metal) capacitor was used. The wiring PL is provided under the trench capacitor.

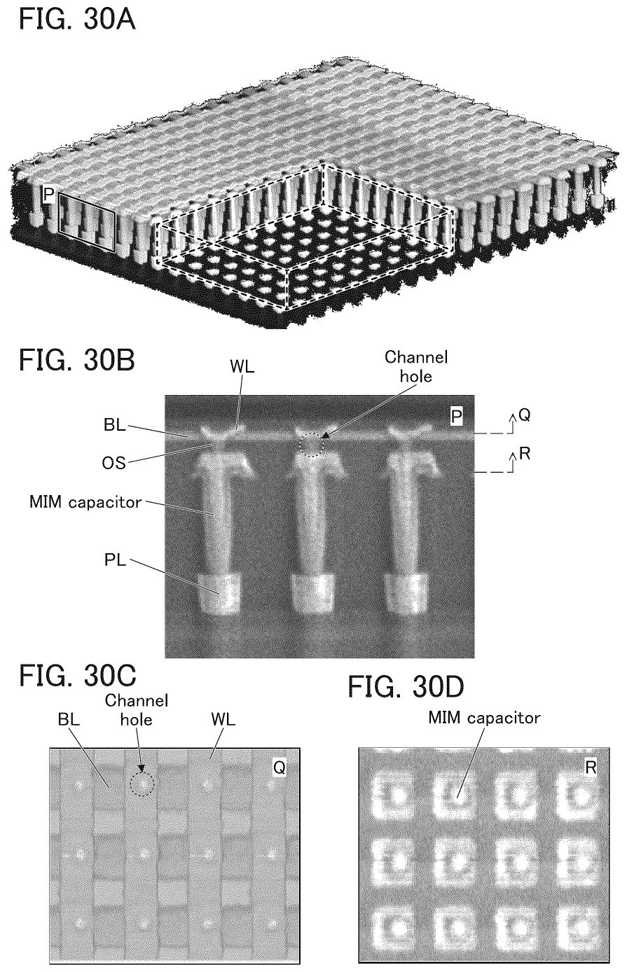

FIG. 30A shows a 3D image created by performing continuous cross-sectional observation (slice and view) on the fabricated memory device with a scanning electron microscope (SEM: Scanning Electron Microscopy). The slice pitch is approximately 10 nm. FIG. 30A shows a region of 4 μm×5 μm. A region denoted by dashed lines is a region that is not displayed.

FIG. 30B is an enlarged view of a region P in FIG. 30A. FIG. 30C and FIG. 30D are cross-sectional views at a height Q and a height R, respectively, in FIG. 30B.

Next, the electrical characteristics of the fabricated vertical transistors are described. In the fabricated vertical transistor, an oxide semiconductor is used as a semiconductor where a channel is formed, and the channel hole has a diameter of approximately 60 nm and a depth (channel length) of approximately 35 nm. For the oxide semiconductor, an approximately 5-nm-thick In—Ga—Zn oxide film formed by an ALD method and an approximately 2-nm-thick In—Ga—Zn oxide film formed by a sputtering method were used. As for a source electrode and a drain electrode, a Si-containing In-Sn oxide film formed by a sputtering method was used for the upper electrode, and stacked films of a Ti nitride film, a W film, and a Si-containing In-Sn oxide film were used for the lower electrode.

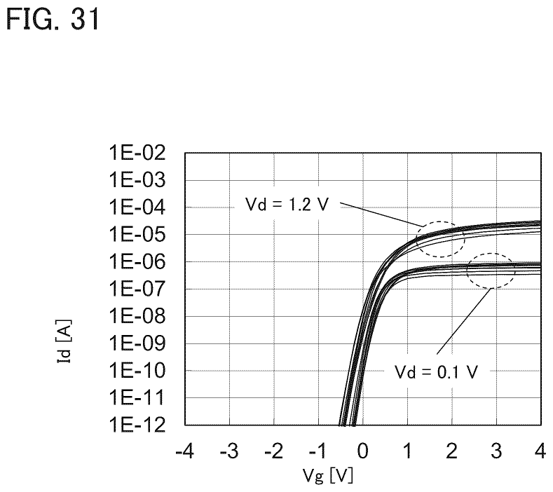

FIG. 31 shows the Id-Vg characteristics of the fabricated vertical transistors. In FIG. 31, the vertical axis represents a drain current (Id [A]) and the horizontal axis represents a gate voltage (Vg [V]). FIG. 31 shows two kinds of electrical characteristics with a drain voltage (Vd) set to 0.1 V and 1.2 V. The number of transistors subjected to each of the measurements is nine. As shown in FIG. 31, the fabricated vertical transistors were demonstrated to have an extremely low off-state current, an adequately high on/off ratio, and favorable electrical characteristics.

### EXAMPLE 2

In this example, the operating speeds of the writing operation and the reading operation of one embodiment of the present invention were estimated. In this example, the estimated operating speed of the semiconductor device 10D in FIG. 11 described in Embodiment 2 will be described.

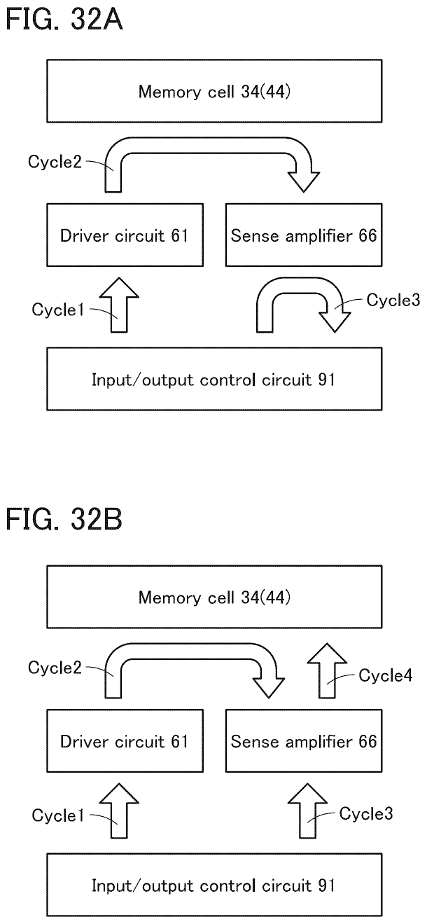

Here, the overview of the operation of the semiconductor device 10D is described with reference to FIG. 32A and FIG. 32B. FIG. 32A is a diagram illustrating the reading operation of the semiconductor device 10D. FIG. 32B is a diagram illustrating the writing operation of the semiconductor device 10D.

An input/output control circuit 91 has a function of controlling reading of information to the semiconductor device 10D and writing of information from the semiconductor device 10D. The input/output control circuit 91 has a function of supplying the signal BW, the signal CE, the signal GW, the signal CLK, the signal WAKE, the signal ADDR, the signal PON1, and the signal PON2 to the semiconductor device 10D. Data (the signal WDA) to be written to the semiconductor device 10D is supplied from the input/output control circuit 91 to the semiconductor device 10D. Data (the signal RDA) read from the semiconductor device 10D is supplied to the input/output control circuit 91.

First, the overview of the data reading operation is described (FIG. 32A). The data reading operation is executed in synchronization with a clock signal (the signal CLK). In the first cycle of the signal CLK (Cycle1), a row address of a memory cell from which data is read is supplied from the input/output control circuit 91 to the driver circuit 61. In the second cycle of the signal CLK (Cycle2), a wiring WL specified by the row address is selected, and data of the memory cell connected to the wiring WL is supplied to the wiring BL connected to the sense amplifier circuit 66. In the third cycle of the signal CLK (Cycle3), the data supplied to the wiring BL is amplified by the sense amplifier circuit 66, and the amplified data is supplied to the input/output control circuit 91.

In this manner, data can be read in three cycles. In the case where the frequency of the signal CLK is 500 MHz, the time required for one cycle is 2 ns. In this case, the time required for data reading is 6 ns.

Next, the overview of the data writing operation is described (FIG. 32B). The data writing operation is also executed in synchronization with the clock signal (the signal CLK). In the first cycle of the signal CLK (Cycle1), a row address of a memory cell to which data is to be written is supplied from the input/output control circuit 91 to the driver circuit 61. In the second cycle of the signal CLK (Cycle2), a wiring WL specified by the row address is selected, and a storage node of the memory cell connected to the wiring WL is connected to the sense amplifier circuit 66 through the wiring BL. In the third cycle of the signal CLK (Cycle3), the signal WDA is supplied from the input/output control circuit 91 to the sense amplifier circuit 66. Moreover, the signal WDA amplified by the sense amplifier circuit 66 is supplied to the wiring BL. In the fourth cycle of the signal CLK (Cycle4), the signal WDA is written to the memory cell.

In this manner, data can be read in four cycles. In the case where the frequency of the signal CLK is 500 MHz, the time required for data writing is 8 ns.

### Supplementary Notes on the Description in This Specification and the Like

The description of the above embodiments and each structure in the embodiments are noted below.

One embodiment of the present invention can be constituted by appropriately combining a structure described in an embodiment with any of the structures described in the other embodiments. In the case where a plurality of structure examples are shown in one embodiment, the structure examples can be combined as appropriate.

Note that content (or part of the content) described in one embodiment can be applied to, combined with, or replaced with another content (or part of the content) described in the embodiment and/or content (or part of the content) described in another embodiment or other embodiments.

Note that in each embodiment, a content described in the embodiment is a content described using a variety of diagrams or a content described with text disclosed in the specification.

By combining a diagram (or part thereof) described in one embodiment with another part of the diagram, a different diagram (or part thereof) described in the embodiment, and/or a diagram (or part thereof) described in another embodiment or other embodiments, much more diagrams can be formed.

In this specification and the like, components are classified on the basis of the functions and shown as blocks independent of each other in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

In the drawings, the size, the layer thickness, or the region is shown with given magnitude for description convenience. Thus, the size, the layer thickness, or the region is not limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relation of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, “voltage” and “potential” can be interchanged with each other as appropriate. The voltage refers to a potential difference from a reference potential, and when the reference potential is a ground voltage, for example, the voltage can be rephrased as the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or the situation. For example, the term “conductive layer” can be replaced with the term “conductive film” in some cases. As another example, the term “insulating film” can be changed to the term “insulating layer” in some cases.

In this specification and the like, a switch has a function of controlling whether current flows or not by being in a conducting state (an on state) or a non-conducting state (an off state). Alternatively, a switch has a function of selecting and changing a current path.

In this specification and the like, channel length of a planar transistor refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

### REFERENCE NUMERALS

10: semiconductor device, 20: element layer, 21: sense amplifier circuit, 22: sense amplifier circuit, 25: arithmetic portion, 26: register, 27: L1 cache, 28: L2 cache, 29: L3 cache, 30: element layer, 33: storage portion, 34: memory cell, 40: element layer, 43: storage portion, 44: memory cell

1. A semiconductor device comprising:
a first element layer;
a second element layer stacked over the first element layer; and
a third element layer stacked over the second element layer,
wherein the second element layer comprises a first storage portion,
wherein the third element layer comprises a second storage portion,
wherein the first element layer comprises a first sense amplifier circuit electrically connected to the first storage portion, and a second sense amplifier circuit electrically connected to the second storage portion,
wherein the first sense amplifier circuit and the second sense amplifier circuit each comprise a first transistor comprising a first semiconductor layer comprising silicon in a channel formation region,
wherein the first storage portion and the second storage portion each comprise a second transistor comprising a second semiconductor layer comprising an oxide semiconductor in a channel formation region, and
wherein the third element layer is a stack of a plurality of element layers.

2. A semiconductor device comprising:
a first element layer;
a second element layer stacked over the first element layer; and
a third element layer stacked over the second element layer,
wherein the second element layer comprises a first storage portion,
wherein the third element layer comprises a second storage portion,
wherein the first element layer comprises a first sense amplifier circuit electrically connected to the first storage portion, and a second sense amplifier circuit electrically connected to the second storage portion,
wherein the first sense amplifier circuit and the second sense amplifier circuit each comprise a first transistor comprising a first semiconductor layer comprising silicon in a channel formation region,
wherein the first storage portion comprises a second transistor comprising a second semiconductor layer comprising an oxide semiconductor in a channel formation region,
wherein the second storage portion comprises a third transistor comprising a third semiconductor layer comprising an oxide semiconductor in a channel formation region, and
wherein the third element layer is a stack of a plurality of element layers.

3. The semiconductor device according to claim 1,
wherein the oxide semiconductor comprises In.

4. The semiconductor device according to claim 1,
wherein the first storage portion is configured to serve as a cache memory of an arithmetic portion.

5. The semiconductor device according to claim 2,
wherein the second transistor is a vertical transistor.

6. The semiconductor device according to claim 5,
wherein the second transistor comprises a first gate electrode and a second gate electrode,
wherein the first gate electrode is supplied with a signal for controlling an on or off state of the second transistor, and
wherein the second gate electrode is supplied with a potential for controlling electrical characteristics of the second transistor.

7. The semiconductor device according to claim 2,
wherein the second transistor is a planar transistor, and
wherein the third transistor is a vertical transistor.

8. The semiconductor device according to claim 7,
wherein the second transistor comprises a first gate electrode and a second gate electrode,
wherein the first gate electrode is supplied with a signal for controlling an on or off state of the second transistor, and
wherein the second gate electrode is supplied with a potential for controlling electrical characteristics of the second transistor.

9. The semiconductor device according to claim 1, further comprising:
a switching circuit between the first storage portion and the first sense amplifier circuit and between the second storage portion and the second sense amplifier circuit.

10. The semiconductor device according to claim 2,
wherein the oxide semiconductor comprises In.

12. The semiconductor device according to claim 2,
wherein the first storage portion is configured to serve as a cache memory of an arithmetic portion.

13. The semiconductor device according to claim 2, further comprising:
a switching circuit between the first storage portion and the first sense amplifier circuit and between the second storage portion and the second sense amplifier circuit.
